(19) United States
(12) Patent Application Publication
(10) Pub. No.: US 2012/0213242 A1
(43) Pub. Date: Aug. 23, 2012

(54) SEMICONDUCTOR LASER DEVICE

(75) Inventors: Taketoshi Tanaka, Kyoto (JP); Shinya Takado, Kyoto (JP); Junichi Kashiwagi, Kyoto (JP); Masashi Yamamoto, Kyoto (JP); Ken Nakahara, Kyoto (JP)

(73) Assignee: ROHM CO., LTD., Kyoto (JP)

(21) Appl. No.: 13/398,818

(22) Filed: Feb. 16, 2012

(30) Foreign Application Priority Data
Feb. 17, 2011 (JP) 2011-32279
Jul. 15, 2011 (JP) 2011-156806
Feb. 8, 2012 (JP) 2012-24959

(51) Int. Cl. H01S 5/026

(52) U.S. Cl. 372/50.1

(57) ABSTRACT

A semiconductor laser device includes a nitride semiconductor laminate structure including an n-type clad layer, an n-type guide layer formed on the n-type clad layer, a light emitting layer formed on the n-type guide layer and a p-type semiconductor layer formed on the light emitting layer. The nitride semiconductor laminate structure does not include a p-type semiconductor clad layer. The semiconductor laser device further includes an upper clad layer formed on the p-type semiconductor layer. The upper clad layer includes a first conductive film made of an indium oxide-based material and a second conductive film formed on the first conductive film and made of a zinc oxide-based material, a gallium oxide-based material or a tin oxide-based material.

### CROSS-REFERENCE TO RELATED APPLICATIONS

This application is based upon and claims the benefit of priority from Japanese Patent Application Nos. 2011-032279, filed on Feb. 17, 2011, 2011-156806, filed on Jul. 15, 2011, and 2012-024959, filed on Feb. 8, 2012, the entire contents of which are incorporated herein by reference.

### TECHNICAL FIELD

The present disclosure relates to a semiconductor laser device.

### BACKGROUND

A semiconductor laser device in the related art includes a substrate and a group-III nitride semiconductor laminate structure formed on the substrate. The group-III nitride semiconductor laminate structure is formed by laminating an n-type semiconductor layer, a light emitting layer and a p-type semiconductor layer on each other. The n-type semiconductor layer includes an n-type AlGaN clad layer and an n-type GaN (or InGaN) guide layer. The p-type semiconductor layer includes a p-type AlGaN electron block layer and a p-type GaN (or InGaN) guide contact layer. A p-type transparent electrode made of ZnO makes ohmic contact with the surface of the p-type GaN (or InGaN) guide contact layer. The p-type transparent electrode serves as an upper clad layer.

### SUMMARY

A semiconductor laser device according to one embodiment of the present disclosure includes: a nitride semiconductor laminate structure including an n-type clad layer, an n-type guide layer formed on the n-type clad layer, a light emitting layer formed on the n-type guide layer and a p-type semiconductor layer formed on the light emitting layer, the nitride semiconductor laminate structure not including a p-type semiconductor clad layer; and an upper clad layer formed on the p-type semiconductor layer, the upper clad layer including a first conductive film made of an indium oxide-based material and a second conductive film formed on the first conductive film and made of a zinc oxide-based material, a gallium oxide-based material or a tin oxide-based material.

With this configuration, light is emitted in the light emitting layer by the recombination of the electrons injected from the n-type guide layer and the holes injected from the p-type semiconductor layer. The light is confined between the n-type clad layer and the upper clad layer and is propagated in the direction perpendicular to the laminating direction of the nitride semiconductor laminate structure. In the semiconductor laser device, the resonator end surfaces are formed at the opposite ends in the light propagation direction. The light is resonated and amplified while repeating stimulated emission between the resonator end surfaces. A part of the light is emitted from the resonator end surfaces as laser light.

The nitride semiconductor laminate structure does not include a p-type semiconductor clad layer. In case where the nitride semiconductor laminate structure includes a p-type semiconductor clad layer, the light emitting layer is formed at a relatively low temperature and then the p-type semiconductor clad layer is formed at a temperature higher than the formation temperature of the light emitting layer in the formation process of the nitride semiconductor laminate structure. For that reason, when forming the p-type semiconductor clad layer, it is likely that the light emitting layer suffers from thermal damage. In some embodiments, the nitride semiconductor laminate structure does not include a p-type semiconductor clad layer. It is therefore possible to prevent a disadvantage that the light emitting layer suffers from thermal damage in the formation process of the nitride semiconductor laminate structure.

The upper clad layer may need to have a certain degree of thickness in order to confine the light of the light emitting layer between the upper clad layer and the n-type clad layer. However, the first conductive film made of an indium oxide-based material shows a low formation speed. Therefore, if the upper clad layer is formed of only the first conductive film, it becomes time-consuming to form the upper clad layer. On the other hand, the second conductive film made of a zinc oxide-based material, a gallium oxide-based material or a tin oxide-based material can be formed at a relatively high speed. However, the second conductive film has a large contact resistance with respect to a p-type nitride semiconductor. In some embodiments, the portion of the upper clad layer making contact with the p-type semiconductor layer is formed of the first conductive film made of an indium oxide-based material, thereby reducing the contact resistance. The formation speed of the upper clad layer can be increased by allowing the upper clad layer to include the first conductive film and the second conductive film formed on the first conductive film and made of a zinc oxide-based material, a gallium oxide-based material or a tin oxide-based material. More specifically, the first conductive film is formed to have a required minimum thickness. This makes it possible to shorten the time required in forming the upper clad layer and to enhance the productivity.

A semiconductor laser device of this embodiment includes: a nitride semiconductor laminate structure including an n-type clad layer, an n-type guide layer formed on the n-type clad layer, a light emitting layer formed on the n-type guide layer and a p-type semiconductor layer formed on the light emitting layer; and an upper clad layer formed on the p-type semiconductor layer, the upper clad layer including a first conductive film made of an indium oxide-based material and a second conductive film formed on the first conductive film and made of a zinc oxide-based material, a gallium oxide-based material or a tin oxide-based material, the semiconductor laser device not comprising a clad layer made of a p-type nitride semiconductor.

With this configuration, light is emitted in the light emitting layer by the recombination of the electrons injected from the n-type guide layer and the holes injected from the p-type semiconductor layer. The light is confined between the n-type clad layer and the upper clad layer and is propagated in the direction perpendicular to the laminating direction of the nitride semiconductor laminate structure. In the semiconductor laser device, the resonator end surfaces are formed at the opposite ends in the light propagation direction. The light is resonated and amplified while repeating stimulated emission between the resonator end surfaces. A part of the light is emitted from the resonator end surfaces as laser light.

The semiconductor laser device does not include a clad layer made of a p-type nitride semiconductor (called a p-type semiconductor clad layer). In case where the semiconductor laser device includes a p-type semiconductor clad layer, the p-type semiconductor clad layer is included in the p-type semiconductor layer of the nitride semiconductor laminate structure. In this case, the light emitting layer is formed at a relatively low temperature and the p-type semiconductor clad layer is formed at a temperature higher than the formation temperature of the light emitting layer in the formation process of the nitride semiconductor laminate structure. For that reason, when forming the p-type semiconductor clad layer, it is likely that the light emitting layer suffers from thermal damage. In some embodiments, the semiconductor laser device does not include a p-type semiconductor clad layer. It is therefore possible to prevent a disadvantage that the light emitting layer suffers from thermal damage in the formation process of the nitride semiconductor laminate structure.

The upper clad layer may need to have a certain degree of thickness in order to confine the light of the light emitting layer between the upper clad layer and the n-type clad layer. However, the first conductive film made of an indium oxide-based material shows a low formation speed. Therefore, if the upper clad layer is formed of only the first conductive film, it becomes time-consuming to form the upper clad layer. On the other hand, the second conductive film made of a zinc oxide-based material, a gallium oxide-based material or a tin oxide-based material can be formed at a relatively high speed. However, the second conductive film has a large contact resistance with respect to a p-type nitride semiconductor. In some embodiments, the portion of the upper clad layer making contact with the p-type semiconductor layer is formed of the first conductive film made of an indium oxide-based material, thereby reducing the contact resistance. The formation speed of the upper clad layer can be increased by allowing the upper clad layer to include the first conductive film and the second conductive film formed on the first conductive film and made of a zinc oxide-based material, a gallium oxide-based material or a tin oxide-based material. More specifically, the first conductive film is formed to have a required minimum thickness. This makes it possible to shorten the time required in forming the upper clad layer and to enhance the productivity.

A semiconductor laser device includes: a nitride semiconductor laminate structure including an n-type clad layer, an n-type guide layer formed on the n-type clad layer, a light emitting layer formed on the n-type guide layer and a p-type semiconductor layer formed on the light emitting layer; and an upper clad layer formed on the p-type semiconductor layer, the upper clad layer including a first conductive film made of an indium oxide-based material and a second conductive film formed on the first conductive film and made of a zinc oxide-based material, a gallium oxide-based material or a tin oxide-based material, the p-type semiconductor layer including a p-type guide layer formed in a surface layer portion near the upper clad layer, the p-type guide layer making contact with the first conductive film.

With this configuration, light is emitted in the light emitting layer by the recombination of the electrons injected from the n-type guide layer and the holes injected from the p-type semiconductor layer. The light is confined between the n-type clad layer and the upper clad layer and is propagated in the direction perpendicular to the laminating direction of the nitride semiconductor laminate structure. In the semiconductor laser device, the resonator end surfaces are formed at the opposite ends in the light propagation direction. The light is resonated and amplified while repeating stimulated emission between the resonator end surfaces. A part of the light is emitted from the resonator end surfaces as laser light.

The upper clad layer may need to have a certain degree of thickness in order to confine the light of the light emitting layer between the upper clad layer and the n-type clad layer. However, the first conductive film made of an indium oxide-based material shows a low formation speed. Therefore, if the upper clad layer is formed of only the first conductive film, it becomes time-consuming to form the upper clad layer. On the other hand, the second conductive film made of a zinc oxide-based material, a gallium oxide-based material or a tin oxide-based material can be formed at a relatively high speed. However, the second conductive film has a large contact resistance with respect to a p-type nitride semiconductor. In some embodiments, the portion of the upper clad layer making contact with the p-type semiconductor layer (the p-type guide layer) is formed of the first conductive film made of an indium oxide-based material, thereby reducing the contact resistance. The formation speed of the upper clad layer can be increased by allowing the upper clad layer to include the first conductive film and the second conductive film formed on the first conductive film and made of a zinc oxide-based material, a gallium oxide-based material or a tin oxide-based material. More specifically, the first conductive film may be formed to have a required minimum thickness. This makes it possible to shorten the time required in forming the upper clad layer and to enhance the productivity.

The p-type guide layer may be made of InGaN. This p-type guide layer can be formed at a lower temperature as compared with a case where the p-type guide layer is composed to include Al. Accordingly, it is possible to further reduce the thermal damage to the light emitting layer.

A semiconductor laser device of this embodiment includes: a nitride semiconductor laminate structure including an n-type clad layer, an n-type guide layer formed on the n-type clad layer, a light emitting layer formed on the n-type guide layer and a p-type semiconductor layer formed on the light emitting layer; an insulation film formed on the p-type semiconductor layer, the insulation film having an opening; and an upper clad layer formed on the insulation film to make contact with the p-type semiconductor layer through the opening, the upper clad layer including a first conductive film formed on the insulation film to make contact with the p-type semiconductor layer through the opening and made of an indium oxide-based material and a second conductive film formed on the first conductive film and made of a zinc oxide-based material, a gallium oxide-based material or a tin oxide-based material.

With this configuration, light is emitted in the light emitting layer by the recombination of the electrons injected from the n-type guide layer and the holes injected from the p-type semiconductor layer. The light is confined between the n-type clad layer and the upper clad layer and is propagated in the direction perpendicular to the laminating direction of the nitride semiconductor laminate structure. In the semiconductor laser device, the resonator end surfaces are formed at the opposite ends in the light propagation direction. The light is resonated and amplified while repeating stimulated emission between the resonator end surfaces. A part of the light is emitted from the resonator end surfaces as laser light.

The insulation film having the opening is formed on the p-type semiconductor layer. The upper clad layer is formed on the insulation film so as to make contact with the p-type semiconductor layer through the opening. In the area other than the opening, the insulation film keeps the p-type semiconductor layer and the upper clad layer insulated from each other and confines the light traveling from the p-type semiconductor layer toward the upper clad layer.

The upper clad layer serves as an electrode for supplying an electric current to the p-type semiconductor layer. The upper clad layer extends into the opening of the insulation film and makes contact with the p-type semiconductor layer. Thus the electric connection between the upper clad layer and the p-type semiconductor layer is limited to the inside of the opening, which makes it possible to form a current confinement structure. In a typical semiconductor laser device, a current confinement structure is formed by, e.g., forming a ridge portion in the p-type semiconductor layer. When etching is performed to form the ridge portion, defects are generated in the semiconductor crystals existing on the side surfaces and the base of the ridge portion. Thus the device properties are likely to grow worse. In order to protect the thin ridge portion from external stresses and to prevent breakage of the device, die-bonding with respect to a mounting substrate cannot be performed in a so-called junction-down posture (a downward junction posture in which the ridge portion faces the mounting substrate). The mounting state is limited to a junction-up posture (an upward junction posture) in such cases. In some embodiments, the nitride semiconductor laminate structure does not have any ridge portion. No ridge portion exists in the upper clad layer. The upper clad layer extends into the opening of the insulation film and makes contact with the p-type semiconductor layer. Accordingly, there is no likelihood that the device properties grow worse due to the etching otherwise performed to form a ridge portion. It is also possible to take a junction-down mounting posture (a downward junction posture).

If the bonding (die-bonding) with respect to the mounting substrate is performed by a junction-down method, the heat generated in the light emitting layer can be dissipated from the upper clad layer to the mounting substrate. This makes it possible to efficiently cool the semiconductor laser device and to enhance the temperature characteristics of the semiconductor laser device.

The upper clad layer may need to have a certain degree of thickness in order to confine the light of the light emitting layer between the upper clad layer and the n-type clad layer. However, the first conductive film made of an indium oxide-based material shows a low formation speed. Therefore, if the upper clad layer is formed of only the first conductive film, it becomes time-consuming to form the upper clad layer. On the other hand, the second conductive film made of a zinc oxide-based material, a gallium oxide-based material or a tin oxide-based material can be formed at a relatively high speed. However, the second conductive film has a large contact resistance with respect to a p-type nitride semiconductor. In some embodiments, the portion of the upper clad layer making contact with the p-type semiconductor layer (the p-type guide layer) is formed of the first conductive film made of an indium oxide-based material, thereby reducing the contact resistance. The formation speed of the upper clad layer can be increased by allowing the upper clad layer to include the first conductive film and the second conductive film formed on the first conductive film and made of a zinc oxide-based material, a gallium oxide-based material or a tin oxide-based material. More specifically, the first conductive film is formed to have a required minimum thickness. This makes it possible to shorten the time required in forming the upper clad layer and to enhance the productivity.

The opening may have a width of 1 μm or more and 100 μm or less when seen in a plan view from a thickness direction of the insulation film.

The insulation film may have a thickness of 200 nm or more and 400 nm or less. With this configuration, it is possible to improve the insulation between the p-type semiconductor layer and the upper clad layer in the area other than the opening and to enhance the effect of confinement of the light traveling from the p-type semiconductor layer toward the upper clad layer.

The first conductive film may have an electron concentration of 1×10¹⁹ cm ⁻³ or more. The first conductive film may have a transmittance of 70% or more (namely, may be transparent or close to transparent) with respect to an emission wavelength of the light emitting layer. Similarly, the second conductive film may have a transmittance of 70% or more (namely, may be transparent or close to transparent) with respect to an emission wavelength of the light emitting layer.

The first conductive film may include Sn at a composition ratio of 3% or more. With this configuration, it is possible to enhance the electric conductivity of the first conductive film.

A contact resistance between the p-type semiconductor layer and the first conductive film may be 1×10⁻³ Ω·cm² or less.

The first conductive film may be made of ITO. This makes it possible to reduce the contact resistance between the first conductive film and the p-type semiconductor layer.

The first conductive film may have a thickness of 2 nm or more and 30 nm or less. With this configuration, it is possible to minimize the time required in forming the first conductive film and to increase the formation speed of the upper clad layer.

The second conductive film may be made of ZnO including group-III atoms at a concentration of 1×10¹⁹ cm ⁻³ or more. The second conductive film may be made of MgZnO including group-III atoms at a concentration of 1×10¹⁹ cm⁻³ or more. The second conductive film may be made of MgZnO including group-III atoms at a concentration of 1×10¹⁹ cm⁻³ or more and having an Mg composition ratio of 50% or less. The group-III atoms may be Ga atoms or Al atoms.

The second conductive film may have a thickness of 400 nm or more and 600 nm or less. With this configuration, the second conductive film has a specified thickness. This makes it possible to enhance the effect of confining the light between the upper clad layer and the n-type clad layer.

The first conductive film and the second conductive film may be smaller in refractive index than the light emitting layer. The p-type semiconductor layer may include Mg at a concentration of 1×10¹⁹ cm⁻³ or more. The light emitting layer may be made of InGaN.

A semiconductor laser device according to other embodiments of the present disclosure includes: a nitride semiconductor laminate structure including an n-type clad layer, an n-type guide layer formed on the n-type clad layer, a light emitting layer formed on the n-type guide layer and a p-type semiconductor layer formed on the light emitting layer; a first conductive film formed on the p-type semiconductor layer and made of an indium oxide-based material; a second conductive film formed on the first conductive film and made of a zinc oxide-based material, a gallium oxide-based material or a tin oxide-based material, the p-type semiconductor layer including an electron block layer made of p-type AlGaN or p-type AlInGaN having an Al composition ratio of 18% or more, the p-type semiconductor layer having a stripe-shaped ridge portion extending in a resonator direction, the p-type semiconductor layer having a thickness of 50 nm or more in the ridge portion; and an insulation film making contact with the p-type semiconductor layer at opposite lateral sides of the ridge portion, the first conductive film making contact with the p-type semiconductor layer in the ridge portion and extending over the insulation film.

With this configuration, the first and second conductive films serve as an upper clad layer and contribute to the light confinement in the light emitting layer. The first conductive film made of an indium oxide-based material has a low contact resistance with respect to the p-type nitride semiconductor. The second conductive film made of a zinc oxide-based material, a gallium oxide-based material or a tin oxide-based material shows a high growth rate. Accordingly, the electrode made up of the first and second conductive films has a low contact resistance with respect to the p-type semiconductor layer and can be formed into a necessary thickness for light confinement within a short period of time.

In some embodiments, the p-type semiconductor layer includes the electron block layer made of p-type AlGaN or p-type AlInGaN having an Al composition ratio of 18% or more. Thus the p-type semiconductor layer can reflect electrons toward the light emitting layer and can increase the efficiency of electron injection to the light emitting layer. The stripe-shaped ridge portion extending in the resonator direction is formed in the p-type semiconductor layer. The first conductive film makes contact with the ridge portion. The insulation film is arranged at the opposite lateral sides of the ridge portion to make contact with the p-type semiconductor layer. It is therefore possible to form a current confinement structure. Moreover, the insulation film having low refractive index than the p-type semiconductor layer can be arranged nearer to the light emitting layer. Thus the light confinement in the light emitting layer in the horizontal direction (the direction orthogonal to the resonator direction and the laminating direction of the nitride semiconductor laminate structure) gets enhanced. In other words, the light confinement in the vertical direction (the laminating direction of the nitride semiconductor laminate structure) can be enhanced by setting the thickness of the p-type semiconductor layer in the ridge portion equal to or larger than 50 nm At the same time, the light confinement in the horizontal direction can be enhanced by arranging the insulation film nearer to the light emitting layer. This can contribute to the reduction of an oscillation threshold value.

The electron block layer may be arranged within the p-type semiconductor layer in a position deeper than the front surface of the p-type semiconductor layer at the opposite lateral sides of the ridge portion. Thus the electron block layer can be arranged over the entire area opposing to the light emitting layer. This makes it possible to increase the efficiency of electron injection to the light emitting layer.

In case where the thickness of the p-type semiconductor layer is less than 50 nm, the insulation film can be brought near the light emitting layer even if the ridge portion is not formed. This makes it possible to sufficiently confine the light in the horizontal direction.

A semiconductor laser device according to some other embodiments of the present disclosure includes: a nitride semiconductor laminate structure including an n-type clad layer, an n-type guide layer formed on the n-type clad layer, a light emitting layer formed on the n-type guide layer and a p-type semiconductor layer formed on the light emitting layer; a first conductive film formed on the p-type semiconductor layer and made of an indium oxide-based material; and a second conductive film formed on the first conductive film and made of a zinc oxide-based material, a gallium oxide-based material or a tin oxide-based material, the p-type semiconductor layer including a first p-type guide layer formed on the light emitting layer and a second p-type guide layer formed on the first p-type guide layer, the second p-type guide layer having a thickness of 10 nm or more and 50 nm or less, the second p-type guide layer doped with a p-type impurity (e.g., Mg) at a concentration of 1×10²⁰ cm⁻³ or more.

With this configuration, the first and second conductive films serve as an upper clad layer and contribute to the light confinement in the light emitting layer. The first conductive film made of an indium oxide-based material has a low contact resistance with respect to the p-type nitride semiconductor. The second conductive film made of a zinc oxide-based material, a gallium oxide-based material or a tin oxide-based material shows a high growth rate. Accordingly, the electrode made up of the first and second conductive films has a low contact resistance with respect to the p-type semiconductor layer and can be formed into a necessary thickness for light confinement within a short period of time.

In some of these embodiments, the p-type semiconductor layer includes the first p-type guide layer formed on the light emitting layer and the second p-type guide layer formed on the first p-type guide layer. The first p-type guide layer and the second p-type guide layer contribute to the carrier confinement and the light confinement in the light emitting layer. The second p-type guide layer plays the role of a contact layer making contact with the first and second conductive films. The second p-type guide layer has a thickness of 10 nm or more and 50 nm or less and, therefore, can provide a carrier confinement effect and a light confinement effect. The second p-type guide layer is doped with a p-type impurity (e.g., Mg) at a concentration of 1×10²⁰ cm ⁻³ or more. This reduces the contact resistance between the second p-type guide layer and the first conductive film. However, the p-type nitride semiconductor layer doped with a p-type impurity at a concentration of 1×10²⁰ cm⁻³ or more has an increased electric resistance. In view of this, the thickness of the p-type nitride semiconductor layer is set equal to or smaller than 50 nm, thereby reducing the series resistance. This makes it possible to reduce the series resistance of the semiconductor laser device and to restrain heat generation in the semiconductor laser device, which contributes to the reduction of an oscillation threshold value. The lower limit value of the thickness of the nitride semiconductor layer required to dope the nitride semiconductor layer with a p-type impurity (e.g., Mg) at a concentration of 1×10²⁰ cm⁻³ or more is 10 nm.

For example, the p-type semiconductor layer may have a ridge portion formed into a stripe shape to extend along the resonator direction. If the second p-type guide layer is formed to have a thickness of 50 nm, a width of 2 μm and a length (resonator length) of 30 μm in the ridge portion and if the doping concentration of a p-type impurity (e.g., Mg) in the second p-type guide layer is 1×10²⁰ cm⁻³ or more, the electric resistance in the second p-type guide layer can be made equal to or smaller than 8 Ω.

A semiconductor laser device according to another embodiment of the present disclosure includes: a nitride semiconductor laminate structure including an n-type clad layer, an n-type guide layer formed on the n-type clad layer, a light emitting layer formed on the n-type guide layer and a p-type semiconductor layer formed on the light emitting layer; a first conductive film formed on the p-type semiconductor layer and made of an indium oxide-based material; and a second conductive film formed on the first conductive film and made of a zinc oxide-based material, a gallium oxide-based material or a tin oxide-based material, the p-type semiconductor layer including a first p-type guide layer formed on the light emitting layer, an electron block layer formed on the first p-type guide layer and made of p-type AlGaN or p-type AlInGaN having an Al composition ratio of 18% or more and a second p-type guide layer formed on the electron block layer, the second p-type guide layer having a thickness of 10 nm or more and 50 nm or less, the second p-type guide layer doped with a p-type impurity (Mg) at a concentration of 1×10²⁰ cm ⁻³ or more.

With this configuration, the first and second conductive films serve as an upper clad layer and contribute to the light confinement in the light emitting layer. The first conductive film made of an indium oxide-based material has a low contact resistance with respect to the p-type nitride semiconductor. The second conductive film made of a zinc oxide-based material, a gallium oxide-based material or a tin oxide-based material shows a high growth rate. Accordingly, the electrode made up of the first and second conductive films has a low contact resistance with respect to the p-type semiconductor layer and can be formed into a necessary thickness for light confinement within a short period of time.

In some embodiments, the p-type semiconductor layer includes the electron block layer arranged between the first and second p-type guide layers and made of p-type AlGaN or p-type AlInGaN having an Al composition ratio of 18% or more. This makes it possible to reflect electrons toward the light emitting layer and to increase the efficiency of electron injection to the light emitting layer.

In some embodiments, the first and second p-type guide layers arranged to interpose the electron block layer therebetween contribute to the carrier confinement and the light confinement in the light emitting layer. The second p-type guide layer plays the role of a contact layer making contact with the first and second conductive films. The second p-type guide layer has a thickness of 10 nm or more and 50 nm or less and, therefore, can provide a carrier confinement effect and a light confinement effect. The second p-type guide layer is doped with a p-type impurity (e.g., Mg) at a concentration of 1×10²⁰ cm ⁻³ or more. This reduces the contact resistance between the second p-type guide layer and the first conductive film. However, the p-type nitride semiconductor layer doped with a p-type impurity at a concentration of 1×10²⁰ cm⁻³ or more has an increased electric resistance. In view of this, the thickness of the p-type nitride semiconductor layer is set equal to or smaller than 50 nm, thereby reducing the series resistance. This makes it possible to reduce the series resistance of the semiconductor laser device and to restrain heat generation in the semiconductor laser device, which contributes to the reduction of an oscillation threshold value. The lower limit value of the thickness of the nitride semiconductor layer required to dope the nitride semiconductor layer with a p-type impurity (e.g., Mg) at a concentration of 1×10²⁰ cm⁻³ or more is 10 nm.

For example, the p-type semiconductor layer may have a ridge portion formed into a stripe shape to extend along the resonator direction. In this case, the ridge portion may be formed in the second p-type guide layer. The electron block layer may be arranged in a position deeper than the front surface of the second p-type guide layer at the opposite lateral sides of the ridge portion.

The insulation film may be arranged at the opposite lateral sides of the ridge portion. This makes it possible to arrange the insulation film nearer to the light emitting layer even when the second p-type guide layer is formed relatively thick for the purpose of light confinement in the vertical direction. Accordingly, it is possible to enhance the light confinement in the horizontal direction, thereby reducing the oscillation threshold value.

The first conductive film may be made of ITO (InₓSn₁₋ₓO, where 0.9≦x<1) having an indium composition ratio of 90% or more.

The first conductive film and the second conductive film may have a total thickness of 400 nm or more. This enables the first and second conductive films to have a sufficient light confinement function.

In some embodiments, the semiconductor laser device may further include: a p-side electrode pad formed on the second conductive film, the second conductive film being larger in width in a direction orthogonal to the resonator direction than the p-side electrode pad. With this configuration, it is possible to connect the semiconductor laser device to the outside through the p-side electrode pad. The p-side electrode pad is smaller in width than the second conductive film. Thus the etching can be stopped in the second conductive film when patterning the p-side electrode pad. In other words, the p-side electrode pad can be patterned by using the second conductive film as an etching stopper.

The p-side electrode pad may include, e.g., Au (gold). In this case, the process for forming the p-side electrode pad includes a step of forming an Au film (electrode pad film) and a step of patterning the Au film by dry etching (e.g., reactive ion etching). In this case, the second conductive film made of a zinc oxide-based material, a gallium oxide-based material or a tin oxide-based material is resistant to the reactive ion etching performed with respect to Au. Thus the etching of the Au film is stopped in the second conductive film. In a case where the base film existing under the electrode pad film is the insulation film (e.g., a silicon oxide film), it is sometimes the case that the insulation film has no resistance to the etching performed with respect to the electrode pad film. Therefore, if the insulation film through which to partially expose the p-type semiconductor layer is formed on the p-type semiconductor layer, it is preferred that the second conductive film be formed to extend over the insulation film. By forming the p-side electrode pad to have a width smaller than the width of the second conductive film, the p-side electrode pad can be patterned using the second conductive film as an etching stopper.

In case where the insulation film is formed on the p-type semiconductor layer and the edge portion of the p-side electrode pad makes contact with the insulation film, it is likely that, when etching is performed to pattern the p-side electrode pad, the insulation film is damaged and the p-type semiconductor layer is exposed. In this case, there is a likelihood that, when an attempt is made to mount the semiconductor laser device on a substrate by a junction-down method, a brazing material such as a solder or the like comes into contact with the p-type semiconductor layer to thereby form an undesired current path. This problem can be avoided by employing the afore-mentioned configuration in which the p-side electrode pad is formed to have a width smaller than the width of the second conductive film.

In some embodiments, the semiconductor laser device may further include: a mount member having a device mount surface, the p-side electrode pad arranged to face the device mount surface and bonded to the device mount surface. With this configuration, it is possible to provide a semiconductor laser device mounted on the mount member by a so-called junction-down method. This makes it possible to dissipate heat through the mount member and to increase the oscillation efficiency of the semiconductor laser device. Since the p-side electrode pad is smaller in width than the second conductive film, it is possible to restrain the brazing material such as a solder or the like from flowing out from the area of the nitride semiconductor laminate structure. This makes it possible to restrain generation of a connection defect such as a short circuit.

The mount member stated above may be a sub-mount substrate or a stem.

A semiconductor laser device according to another embodiment includes: a nitride semiconductor laminate structure including an n-type clad layer, an n-type guide layer formed on the n-type clad layer, a light emitting layer formed on the n-type guide layer and a p-type semiconductor layer formed on the light emitting layer; a first conductive film formed on the p-type semiconductor layer and made of an indium oxide-based material; and a second conductive film formed on the first conductive film and made of a zinc oxide-based material, a gallium oxide-based material or a tin oxide-based material, the p-type semiconductor layer including a first p-type guide layer formed on the light emitting layer, a p-type electron block layer formed on the first p-type guide layer, a second p-type guide layer formed on the p-type electron block layer, the second p-type guide layer being higher in p-type impurity concentration than the first p-type guide layer, and a p-type contact layer formed on the second p-type guide layer, the p-type contact layer being higher in p-type impurity concentration than the second p-type guide layer.

With this configuration, the first and second conductive films serve as an upper clad layer and contribute to the light confinement in the light emitting layer. The first conductive film made of an indium oxide-based material has a low contact resistance with respect to the p-type nitride semiconductor. The second conductive film made of a zinc oxide-based material, a gallium oxide-based material or a tin oxide-based material shows a high growth rate. Accordingly, the electrode made up of the first and second conductive films has a low contact resistance with respect to the p-type semiconductor layer and can be formed into a necessary thickness for light confinement within a short period of time.

In some embodiments, the p-type semiconductor layer includes the p-type electron block layer arranged between the first and second p-type guide layers. This makes it possible to reflect electrons toward the light emitting layer and to increase the efficiency of electron injection to the light emitting layer. The first and second p-type guide layers arranged to interpose the p-type electron block layer therebetween contribute to the carrier confinement and the light confinement in the light emitting layer. The p-type contact layer makes contact with the second conductive film. Since the p-type contact layer is high in the p-type impurity concentration thereof, the contact resistance between the p-type contact layer and the second conductive film is kept low. The second p-type guide layer is lower in the p-type impurity concentration than the p-type contact layer. The first p-type guide layer is lower in the p-type impurity concentration than the second p-type guide layer. In other words, the p-type impurity concentration grows lower toward the light emitting layer, in which structure the absorption of light by the impurity is restrained.

In some embodiments, at least a portion of the p-type contact layer is dug down to form a ridge portion. This makes it possible to form a current confinement structure in which an electric current is concentrated on the ridge portion. The ridge portion may be formed into a stripe shape to extend along the resonator direction. The insulation film may be arranged at the opposite lateral sides of the ridge portion. Therefore, the light confinement in the vertical direction can be performed by securing, to some extent, the thickness of the p-type semiconductor layer including the p-type contact layer. At the same time, the light confinement in the horizontal direction can be enhanced by arranging the insulation film nearer to the light emitting layer. This makes it possible to reduce the oscillation threshold value.

The second p-type guide layer may have a thickness of 50 nm or less. In particular, if the ridge portion is formed and if the thickness of the second p-type guide layer is set equal to or smaller than 50 nm, the insulation film existing at the opposite lateral sides of the ridge portion can be arranged nearer to the light emitting layer. This makes it possible to further enhance the light confinement in the horizontal direction, which can contribute to the reduction of the oscillation threshold value.

The p-type contact layer may have a p-type impurity concentration of 1×10²⁰ cm ⁻³ or more, and the first p-type guide layer and the second p-type guide layer may have a p-type impurity concentration of 5×10¹⁸ cm⁻³ or more and 5×10¹⁹ cm⁻³ or less. With this configuration, it is possible to reduce the contact resistance between the p-type contact layer and the second conductive film and to restrain the first and second p-type guide layers from absorbing the light.

The p-type semiconductor layer may have a total thickness of 1500 Å or less. This makes it possible to reduce the thickness of the semiconductor laser device.

A semiconductor laser device according to another embodiment of the present disclosure includes: a nitride semiconductor laminate structure including an n-type clad layer, an n-type guide layer formed on the n-type clad layer, a light emitting layer formed on the n-type guide layer and a p-type semiconductor layer formed on the light emitting layer; a first conductive film formed on the p-type semiconductor layer and made of an indium oxide-based material; a second conductive film formed on the first conductive film and made of a zinc oxide-based material, a gallium oxide-based material or a tin oxide-based material; and a p-side electrode pad formed to make contact with the second conductive film, the p-side electrode pad including TiN.

With this configuration, the first and second conductive films serve as an upper clad layer and contribute to the light confinement in the light emitting layer. The first conductive film made of an indium oxide-based material has a low contact resistance with respect to the p-type nitride semiconductor. The second conductive film made of a zinc oxide-based material, a gallium oxide-based material or a tin oxide-based material shows a high growth rate. Accordingly, the electrode made up of the first and second conductive films has a low contact resistance with respect to the p-type semiconductor layer and can be formed into a necessary thickness for light confinement within a short period of time.

In some embodiments, the p-side electrode pad formed to make contact with the second conductive film includes TiN. The TiN included in the p-side electrode pad serves to restrain diffusion of oxygen atoms from the second conductive film when a half-finished device is subjected to heat treatment in the manufacturing process. This makes it possible to retrain or prevent the p-side electrode pad from being highly resistant or being peeled off. In order to form the n-side electrode pad making ohmic contact with an n-type layer, it is sometimes necessary to subject a half-finished device to heat treatment (sintering) at a temperature of 600 degrees C. to 700 degrees C. Even after going through the heat treatment, it is possible to keep the p-side electrode pad including TiN at a low resistance. It is also possible to keep the strong adherence of the p-side electrode pad to the nitride semiconductor laminate structure.

More specifically, the p-side electrode pad may include a laminated electrode film having a Ti layer, a TiN layer and an Au layer laminated in the named order from the side of the second conductive film. With this configuration, it is possible to restrain diffusion of oxygen atoms from the second conductive film. Even when a half-finished device is subjected to heat treatment (at a temperature of, e.g., 400 degrees C. to 900 degrees C.), the p-side electrode pad formed of a laminated electrode film can be kept at a low resistance. It is also possible to keep the strong adherence of the p-side electrode pad to the nitride semiconductor laminate structure. The Ti layer and the TiN layer may be formed by a sputtering method. The Au layer may be formed by a vapor deposition method.

In addition to the Ti/TiN/Au laminated electrode film, a single TiN film, a laminated electrode film formed by laminating a TiN layer and an Au layer in the named order from the front surface of the second conductive film or a laminated electrode film formed by laminating a TiN layer and an Al layer in the named order from the front surface of the second conductive film can be used as the p-side electrode pad.

In some embodiments, the semiconductor laser device may further include: a mount member having a device mount surface, the p-side electrode pad arranged to face the device mount surface and bonded to the device mount surface. With this configuration, it is possible to provide a semiconductor laser device mounted on the mount member by a so-called junction-down method. This makes it possible to dissipate heat through the mount member and to increase the oscillation efficiency of the semiconductor laser device. Since the p-side electrode pad includes TiN, it is possible to prevent oxygen atoms in the second conductive film from being diffused into the p-side electrode pad under the influence of heat generated during an operation and consequently increasing the resistance value. It is also possible to prevent the p-side electrode pad from being peeled off. The mount member may be a sub-mount substrate or a stem.

In some embodiments, the semiconductor laser device may further include: an n-side electrode pad bonded to the nitride semiconductor laminate structure at the opposite side of the light emitting layer from the p-side electrode pad, the n-side electrode pad including TiN.

The n-side electrode pad may include a laminated electrode film having an Al layer, a TiN layer and an Au layer laminated in the named order from the side of the nitride semiconductor laminate structure. In addition, a single TiN film, a laminated electrode film formed by laminating a Al layer and a TiN layer in the named order from the side of the nitride semiconductor laminate structure or a laminated electrode film formed by laminating a TiN layer and an Au layer in the named order from the side of the nitride semiconductor laminate structure can be used as the n-side electrode pad.

In addition, a laminated electrode film formed by laminating an Al contact metal layer, a Ni layer and an Au layer in the named order from the side of the nitride semiconductor laminate structure can be used as the n-side electrode pad. Moreover, a laminated electrode film including an Al contact metal layer, a Pt layer and an Au layer may be used as the n-side electrode pad.

A semiconductor laser device according to another embodiment of the present disclosure includes: a nitride semiconductor laminate structure including an n-type clad layer, an n-type guide layer formed on the n-type clad layer, a light emitting layer formed on the n-type guide layer and a p-type semiconductor layer formed on the light emitting layer; an insulation film formed on the p-type semiconductor layer, the insulation film having an opening; a first conductive film formed on the insulation film to make contact with the p-type semiconductor layer through the opening and made of an indium oxide-based material; a second conductive film formed on the first conductive film and made of a zinc oxide-based material, a gallium oxide-based material or a tin oxide-based material; and a p-side electrode pad formed to make contact with the second conductive film, the p-side electrode pad having a recess portion formed in an area corresponding to the opening.

With this configuration, the first and second conductive films serve as an upper clad layer and contribute to the light confinement in the light emitting layer. The first conductive film made of an indium oxide-based material has a low contact resistance with respect to the p-type nitride semiconductor. The second conductive film made of a zinc oxide-based material, a gallium oxide-based material or a tin oxide-based material shows a high growth rate. Accordingly, the electrode made up of the first and second conductive films has a low contact resistance with respect to the p-type semiconductor layer and can be formed into a necessary thickness for light confinement within a short period of time.

In some embodiments, the insulation film having the opening is formed on the p-type semiconductor layer. The first conductive film makes contact with the p-type semiconductor layer through the opening. Thus a current confinement structure is formed. This makes it possible to efficiently generate laser oscillation. The p-side electrode pad making contact with the second conductive film has a recess portion formed in the area of the p-side electrode pad corresponding to the opening. Accordingly, when the p-side electrode pad is arranged to face a mounting substrate and is bonded thereto by a junction-down method, there is no possibility that a large stress is applied to the area of the p-side electrode pad corresponding to the opening (the area where laser oscillation is generated). It is therefore possible to avoid generation of damage in the light emitting layer during a bonding process. This makes it possible to improve the throughput and reliability of a product manufactured by bonding the semiconductor laser device to the mounting substrate by a junction-down method. Since the junction-down bonding can be employed with ease, it becomes possible to provide a product superior in heat dissipation property.

In some embodiments, the opening may be formed into a stripe, and the first conductive film and the second conductive film may make up a transparent electrode whose width in a direction perpendicular to the stripe is equal to or smaller than a width of the insulation film in the direction perpendicular to the stripe. In this case, the extension direction of the stripe is the resonator direction. Since the width of the first and second conductive films is equal to or smaller than the width of the insulation film, the first conductive film or the second conductive film does not make contact with the nitride semiconductor laminate structure in the area other than the opening. The width of the transparent electrode is set as large as possible within a range not exceeding the width of the insulation film. This makes it possible to increase the width of the p-side electrode pad formed on the transparent electrode. Therefore, when junction-down bonding is employed, heat is efficiently dissipated through the p-side electrode pad.

In some embodiments, the opening may be formed into a stripe, and the first conductive film and the second conductive film may make up a transparent electrode whose width in a direction perpendicular to the stripe is equal to or smaller than a width of the nitride semiconductor laminate structure in the direction perpendicular to the stripe. In this case, the extension direction of the stripe is the resonator direction. The transparent electrode made up of the first and second conductive films may be formed as large as possible within a range not exceeding the width of the nitride semiconductor laminate structure. This makes it possible to increase the width of the p-side electrode pad formed on the transparent electrode. Therefore, when junction-down bonding is employed, heat is efficiently dissipated through the p-side electrode pad.

The width of the p-side electrode pad in the direction orthogonal to the stripe may be set equal to or smaller than the width of the transparent electrode in the direction orthogonal to the stripe. The width of the p-side electrode pad may be set as large as possible within a range not exceeding the width of the transparent electrode. This makes it possible to increase the width of the p-side electrode pad. Therefore, when junction-down bonding is employed, heat is efficiently dissipated through the p-side electrode pad.

In some embodiments, the opening may be formed into a stripe, and the first conductive film and the second conductive film may make up a transparent electrode whose opposite end edges in a direction parallel to the stripe are respectively arranged inward of opposite end edges of the nitride semiconductor laminate structure in the direction parallel to the stripe.

In some embodiments, the opening may be formed into a stripe, and the first conductive film and the second conductive film may make up a transparent electrode having opposite end portions and a central portion arranged along a direction parallel to the stripe, the opposite end portions differing in width from the central portion.

In some embodiments, the p-type semiconductor layer may include a stripe-shaped ridge portion formed to have a height of 0.5 μm or less, the opening formed so as to expose a top surface of the ridge portion. The ridge portion having a height of 0.5 μm or less can have a top surface lower than the front surface of the insulation film. Therefore, even if the ridge portion is formed in the p-type semiconductor layer, the p-side electrode pad can have a recess portion formed in the area corresponding to the opening of the insulation film. This makes it possible to provide a semiconductor laser device having a structure favorable for junction-down bonding, while enhancing the light confinement in the vertical direction by forming the ridge portion in the p-type semiconductor layer.

The p-type semiconductor layer may include a p-type contact layer having a front surface exposed through the opening, the p-type contact layer having a p-type impurity concentration of 1×10²⁰ cm⁻³ or more. With this configuration, it is possible to reduce the contact resistance between the first conductive film and the p-type semiconductor layer. This makes it possible to provide a semiconductor laser device having a low series resistance.

A semiconductor laser device according to other embodiments of the present disclosure includes: a nitride semiconductor laminate structure including an n-type clad layer, an n-type guide layer formed on the n-type clad layer, a light emitting layer formed on the n-type guide layer and a p-type semiconductor layer formed on the light emitting layer, the nitride semiconductor laminate structure having a pair of resonator end surfaces existing at opposite ends in a resonator direction; an insulation film formed on the p-type semiconductor layer, the insulation film having a stripe-shaped opening extending along the resonator direction; a first conductive film formed on the insulation film to make contact with the p-type semiconductor layer through the opening and made of an indium oxide-based material; a second conductive film formed on the first conductive film and made of a zinc oxide-based material, a gallium oxide-based material or a tin oxide-based material; and a p-side electrode pad formed to make contact with the second conductive film, the p-side electrode pad having a pair of end edges respectively flush with the resonator end surfaces.

With this configuration, the first and second conductive films serve as an upper clad layer and contribute to the light confinement in the light emitting layer. The first conductive film made of an indium oxide-based material has a low contact resistance with respect to the p-type nitride semiconductor. The second conductive film made of a zinc oxide-based material, a gallium oxide-based material or a tin oxide-based material shows a high growth rate. Accordingly, the electrode made up of the first and second conductive films has a low contact resistance with respect to the p-type semiconductor layer and can be formed into a necessary thickness for light confinement within a short period of time.

In some of these embodiments, the insulation film having the opening is formed on the p-type semiconductor layer. The first conductive film makes contact with the p-type semiconductor layer through the opening. Thus a current confinement structure is formed. This makes it possible to efficiently generate laser oscillation.

In some of these embodiments, the p-side electrode pad has a pair of end edges respectively flush with a pair of resonator end surfaces. In other words, the p-side electrode pad is formed over the total length in the resonator direction to make contact with the second conductive film. It is therefore possible to uniformly supply an electric current over the total length in the resonator direction. This makes it possible to make the current density constant everywhere along the resonator direction, thereby improving the light output characteristics.

In some embodiments, the p-side electrode pad may be formed of a laminated metal film including a first metal film making contact with the second conductive film and a second metal film (e.g., made of an oxidation-resistant metallic material) formed on the first metal film, the first metal film having opposite end edges in the resonator direction respectively flush with the resonator end surfaces, the second metal film having opposite end edges in the resonator direction respectively arranged inward of the resonator end surfaces by a specified distance.

With this configuration, the first metal film makes contact with the second conductive film over the total length in the resonator direction. This makes it possible to uniformly supply an electric current everywhere along the resonator direction. On the other hand, the opposite end edges of the second metal film are arranged inward of the resonator end surfaces. Accordingly, the second metal film has no influence when the resonator end surfaces are formed by cleaving the substrate. This makes it possible to form good resonator end surfaces, thereby realizing a semiconductor laser device having superior characteristics. In particular, if the second metal film is made of gold (one example of oxidation-resistant metallic materials), the ductility of the second metal film grows higher. In light of this, it is desirable to employ the structure stated above.

In some embodiments, the laminated metal film making up the p-side electrode pad may be arranged between the first metal film and the second metal film and may further include a third metal film resistant to etching of the second metal film. With this configuration, it is possible to etch the second metal film using the third metal film as an etching stopper and to selectively remove the area of the second metal film near the resonator end surfaces.

In some embodiments, the first metal film may be resistant to etching of the second metal film. With this configuration, it is possible to etch the second metal film using the first metal film as an etching stopper and to selectively remove the area of the second metal film near the resonator end surfaces. The first and second metal films may make contact with each other.

### BRIEF DESCRIPTION OF THE DRAWINGS

FIG. 1 is a schematic perspective view for illustrating the configuration of a semiconductor laser device according to a first embodiment of the present disclosure, with certain major portions cut away.

FIG. 2 is a section view taken along line II-II in FIG. 1.

FIG. 3 is a diagrammatic section view illustrating a manufacturing method of the semiconductor laser device shown in FIG. 2.

FIG. 4 is a schematic section view of a semiconductor laser device according to a second embodiment of the present disclosure.

FIG. 5 is a schematic section view of a semiconductor laser device according to a third embodiment of the present disclosure, showing a cross section orthogonal to a resonator direction.

FIG. 6 is a schematic section view of a semiconductor laser device according to a fourth embodiment of the present disclosure, showing a cross section orthogonal to a resonator direction.

FIG. 7 represents the investigation results on the relationship between the thickness of a transparent electrode as an upper clad layer and the threshold current density.

FIG. 8 is a diagrammatic section view showing a structure in which the semiconductor laser device of the third or fourth embodiment is bonded to a sub-mount by a junction-down method.

FIG. 9 is a schematic section view of a semiconductor laser device according to a fifth embodiment of the present disclosure, showing a cross section orthogonal to a resonator direction.

FIG. 10 represents the calculation results on the relationship between the thickness of a p-type GaN contact layer and a second p-type GaN guide layer and the threshold current.

FIG. 11 is a schematic section view of a semiconductor laser device according to a sixth embodiment of the present disclosure, showing a cross section orthogonal to a resonator direction.

FIG. 12A represents the measurement results of the resistance characteristics of electrode pads formed on a ZnO film and made of a Ti/TiN/Au laminated electrode film (working example).

FIG. 12B represents the measurement results of the resistance characteristics of electrode pads formed on a ZnO film and made of a Ti/Ni/Au laminated electrode film (comparative example).

FIG. 12C represents the measurement results of the resistance characteristics of electrode pads formed on a ZnO film and made of a Ti/Au laminated electrode film (comparative example).

FIG. 13A is a section view for illustrating a measurement method of the resistance characteristics.

FIG. 13B is a plan view for illustrating the measurement method of the resistance characteristics.

FIG. 14 is a diagrammatic perspective view showing a structure in which the semiconductor laser device of the sixth embodiment is bonded to a sub-mount by a junction-down method.

FIG. 15 is a schematic perspective view of a semiconductor laser device according to a seventh embodiment of the present disclosure.

FIG. 16A is a diagrammatic plan view of the semiconductor laser device according to the seventh embodiment.

FIG. 16B is a schematic section view of a portion of the semiconductor laser device according to the seventh embodiment of the present disclosure, showing a cross section orthogonal to a resonator direction.

FIG. 17A is a plan view for illustrating a first modified example of the seventh embodiment.

FIG. 17B is a section view for illustrating the first modified example of the seventh embodiment.

FIG. 18A is a plan view for illustrating a second modified example of the seventh embodiment.

FIG. 18B is a section view for illustrating the second modified example of the seventh embodiment.

FIG. 19A is a plan view for illustrating a third modified example of the seventh embodiment.

FIG. 19B is a section view for illustrating the third modified example of the seventh embodiment.

FIG. 20 is a plan view showing a fourth modified example of the seventh embodiment.

FIG. 21 is a plan view showing a fifth modified example of the seventh embodiment.

FIG. 22 is a plan view showing a sixth modified example of the seventh embodiment.

FIG. 23 is a plan view showing a seventh modified example of the seventh embodiment.

FIG. 24 is a schematic partial section view of a semiconductor laser device according to an eighth embodiment of the present disclosure, showing a cross section orthogonal to a resonator direction.

FIG. 25 is a schematic perspective view of a semiconductor laser device according to a ninth embodiment of the present disclosure.

FIG. 26 is a diagrammatic plan view of the semiconductor laser device according to the ninth embodiment.

FIG. 27 is a schematic section view of the semiconductor laser device according to the ninth embodiment, showing a cross section taken along a resonator direction.

FIG. 28 represents the simulation results for calculation of the current densities in the respective portions along the resonator direction.

FIG. 29 is a light output characteristic diagram for illustrating the improvement of the light output characteristics in the ninth embodiment.

FIG. 30 is a schematic perspective view of a semiconductor laser device according to a tenth embodiment of the present disclosure.

FIG. 31 is a schematic plan view of the semiconductor laser device according to the tenth embodiment.

FIG. 32 is a vertical section view of the semiconductor laser device according to the tenth embodiment, which is taken along a resonator direction.

FIG. 33 is a plan view showing a modified example of the ninth embodiment.

FIG. 34 is a plan view showing a modified example of the tenth embodiment.

### DETAILED DESCRIPTION

Certain embodiments of the present disclosure will now be described in detail with reference to the accompanying drawings.

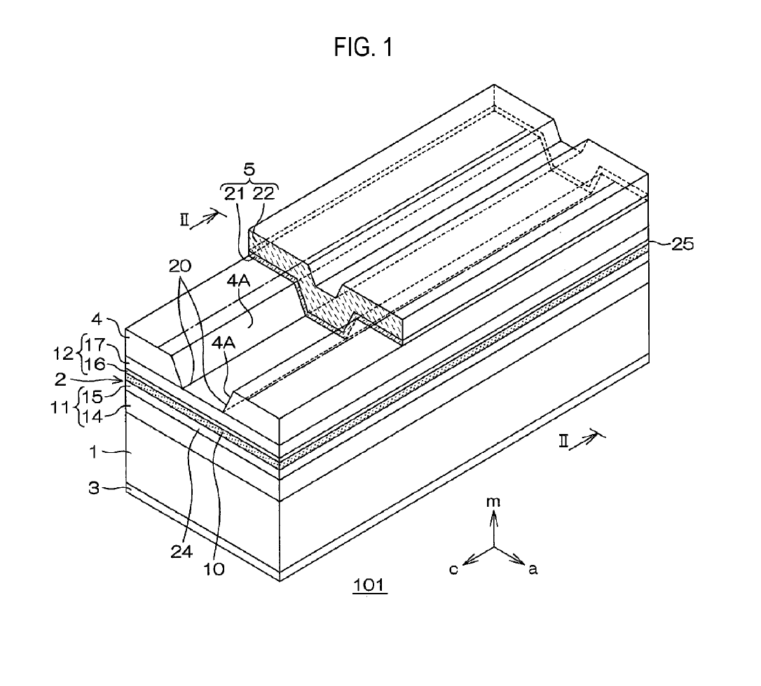

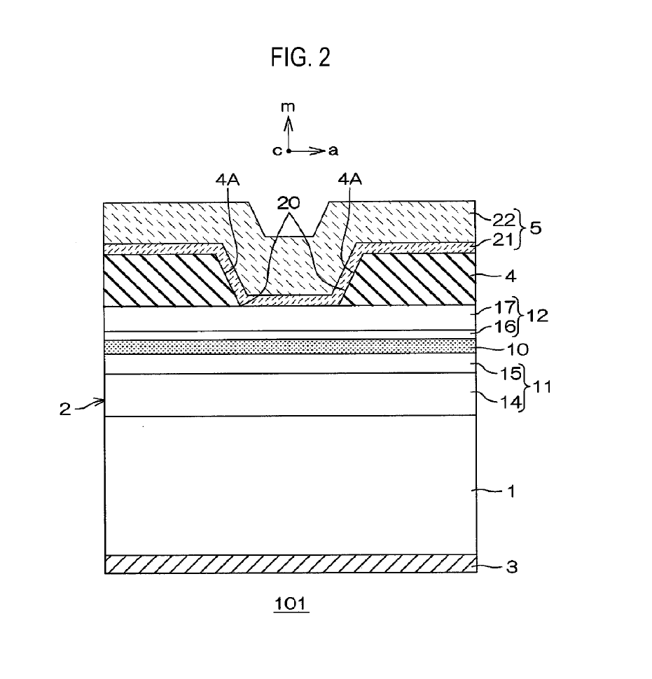

FIG. 1 is a schematic perspective view for illustrating the configuration of a semiconductor laser device 101 according to a first embodiment of the present disclosure, with certain major portions cut away. FIG. 2 is a section view taken along line II-II in FIG. 1.

The semiconductor laser device 101 is a Fabry-Perot type device that includes a substrate 1, a nitride semiconductor laminate structure 2 formed on the substrate 1 by way of crystal growth (epitaxial growth), an n-side electrode pad 3 formed to make contact with a rear surface of the substrate 1 (an opposite surface of the substrate 1 from the nitride semiconductor laminate structure 2), an insulation film 4 formed to make contact with a front surface of the nitride semiconductor laminate structure 2 and a transparent electrode 5 as a p-side electrode formed on the insulation film 4 to make partial contact with the front surface of the nitride semiconductor laminate structure 2. In FIG. 1, for the sake of convenience in description, the transparent electrode 5 is partially cut away to show the cross section of the transparent electrode 5.

In the present embodiment, the substrate 1 is formed of a GaN monocrystalline substrate. The substrate 1 has an m-plane as a major surface. The nitride semiconductor laminate structure 2 is formed by performing crystal growth on the major surface. Accordingly, the nitride semiconductor laminate structure 2 is formed of a nitride semiconductor having an m-plane as a crystal growth major surface. In the respective figures, an m-axis direction, a c-axis direction and an a-axis direction are indicated by arrows.

The nitride semiconductor laminate structure 2 includes a light emitting layer (active layer) 10, an n-type semiconductor layer 11 and a p-type semiconductor layer 12. In the respective figures, the light emitting layer 10 is depicted by dots. The n-type semiconductor layer 11 is arranged at the side of the substrate 1 with respect to the light emitting layer 10. The p-type semiconductor layer 12 is arranged at the side of the transparent electrode 5 with respect to the light emitting layer 10. Thus the light emitting layer 10 is sandwiched between the n-type semiconductor layer 11 and the p-type semiconductor layer 12 to form a double heterojunction structure. Electrons are injected into the light emitting layer 10 from the n-type semiconductor layer 11 and holes are injected into the light emitting layer 10 from the p-type semiconductor layer 12. The electrons and the holes are recombined in the light emitting layer 10, thereby generating light.

The n-type semiconductor layer 11 is formed by laminating an n-type clad layer 14 (having a thickness of, e.g., 1.0 μm) and an n-type guide layer 15 (having a thickness of, e.g., 100 nm) in the named order from the side of the substrate 1.

On the other hand, the p-type semiconductor layer 12 is formed on the light emitting layer 10. The p-type semiconductor layer 12 includes Mg at a concentration of 1×10¹⁹ cm⁻³ or more. The p-type semiconductor layer 12 is formed by laminating a p-type electron block layer 16 (having a thickness of, e.g., 20 nm) and a p-type guide contact layer 17 (having a thickness of, e.g., 100 nm) in the named order from the side of the light emitting layer 10. The p-type guide contact layer 17 is positioned in a surface layer portion of the p-type semiconductor layer 12 near the transparent electrode 5.

The n-type clad layer 14 is formed on the substrate 1. The n-type clad layer 14 provides a light confinement effect by which the light emitted from the light emitting layer 10 is confined in the light emitting layer 10. The n-type clad layer 14 is an n-type semiconductor formed by doping AlGaN with, e.g., Si as an n-type dopant (at a doping concentration of, e.g., 1×10¹⁸ cm⁻³). The n-type clad layer 14 is wider in band gap than the n-type guide layer 15. Thus the n-type clad layer 14 has a refractive index smaller than the refractive index of the n-type guide layer 15. This makes it possible to perform the light confinement, thereby realizing the semiconductor laser device 101 with a low threshold value and a high efficiency.

The n-type guide layer 15 is formed on the n-type clad layer 14. The n-type guide layer 15 is a semiconductor layer providing a carrier confinement effect by which carriers (electrons) are confined in the light emitting layer 10. This makes it possible to increase the efficiency of recombination of electrons and holes in the light emitting layer 10. The n-type guide layer 15 is an n-type semiconductor formed by doping GaN with, e.g., Si as an n-type dopant (at a doping concentration of, e.g., 1×10¹⁸ cm⁻³).

The light emitting layer 10 is formed on the n-type guide layer 15. The light emitting layer 10 has a multiple-quantum well structure including, e.g., InGaN. The light emitting layer 10 is a layer in which light is generated by the recombination of the electrons and the holes and in which the light thus generated is amplified. More specifically, the light emitting layer 10 is formed by alternately and repeatedly laminating an InGaN layer (having a thickness of 100 Å or less, e.g., 3 nm) and a GaN layer (having a thickness of, e.g., 9 nm) more than once. In this case, the InGaN layer is formed to have an In composition ratio of 5% or more, whereby the band gap of the InGaN layer grows relatively small. Thus the InGaN layer becomes a quantum well layer. On the other hand, the GaN layer serves as a barrier layer having a relatively large band gap. For example, the InGaN layer and the GaN layer are alternately laminated twice through seven times to thereby form the light emitting layer 10 having a multiple-quantum well structure. Emission wavelength is set, e.g., equal to or larger than 400 nm and equal to or smaller than 550 nm by adjusting the In composition ratio in the quantum well layer (InGaN layer). In the multiple-quantum well structure, the number of quantum wells including In may be set equal to or less than three.

In order to have the emission wavelength fall within a blue-violet region near 405 nm, the In composition ratio of the quantum well layer may be set equal to 6% through 8% (e.g., 7%). In order to have the emission wavelength fall within a blue region near 460 nm, the In composition ratio of the quantum well layer may be set equal to 12% through 16% (e.g., 14%). In order to have the emission wavelength fall within a green region near 530 nm, the In composition ratio of the quantum well layer may be set equal to 21% through 25% (e.g., 23%).

The p-type electron block layer 16 is formed on the light emitting layer 10. The p-type electron block layer 16 is a p-type semiconductor formed by doping AlGaN with, e.g., Mg as a p-type dopant (at a doping concentration of, e.g., 5×10¹⁸ cm⁻³). The p-type electron block layer 16 prevents electrons from flowing out from the light emitting layer 10, thereby increasing the efficiency of recombination of electrons and holes.

The p-type guide contact layer 17 is formed on the p-type electron block layer 16. The p-type guide contact layer 17 serves not only as a low-resistance layer (contact layer) for making ohmic contact with the transparent electrode 5 but also as a semiconductor layer for generating carrier confinement effect by which carriers (holes) are confined in the light emitting layer 10. This makes it possible to increase the efficiency of recombination of electrons and holes in the light emitting layer 10. The p-type guide contact layer 17 is made of InGaN and is a p-type semiconductor formed by doping InGaN with, e.g., Mg as a p-type dopant at a high concentration (at a doping concentration of, e.g., 3×10¹⁹ cm⁻³).

In the present embodiment, the p-type semiconductor layer 12 is not formed into a ridge shape but is formed to have a flat surface. The insulation film 4 is formed on the p-type semiconductor layer 12 to make contact with the flat surface of the p-type semiconductor layer 12.

The insulation film 4 may be made of, e.g., ZrO₂ or SiO₂. The thickness of the insulation film 4 is 200 nm or more and 400 nm or less. An opening 20 is formed in the insulation film 4. The opening 20 is formed in a transverse direction (a-axis direction) middle portion of the insulation film 4 to have a stripe shape extending over the entire area of the insulation film 4 along the c-axis direction (resonator direction). The opening 20 extends through the insulation film 4 in the thickness direction thereof (in the m-axis direction). In a plan view seen in the thickness direction, the opening 20 has a width of 1 μm or more and 100 μm or less in the a-axis direction (in the direction orthogonal to the resonator direction). The width of the opening 20 grows smaller toward the p-type semiconductor layer 12. For that reason, a pair of lateral surface portions of the insulation film 4 defining the opening 20 in the transverse direction becomes a pair of slant surfaces 4A getting closer to each other as they extend toward the p-type semiconductor layer 12. The front surface of the p-type guide contact layer 17 of the p-type semiconductor layer 12 is exposed in the opening 20.

The transparent electrode 5 is formed on the insulation film 4 to make ohmic contact with the p-type guide contact layer 17 of the p-type semiconductor layer 12 through the opening 20. Accordingly, the transparent electrode 5 is formed on the insulation film 4 and on the p-type semiconductor layer 12 in the opening 20. The transparent electrode 5 is formed by laminating a first conductive film 21 and a second conductive film 22 in the named order from the side of the insulation film 4. The transparent electrode 5 as a whole has a thickness of about 400 nm.

The first conductive film 21 is a transparent oxide film having a thickness of 2 nm or more and 20 nm or less (e.g., 10 nm). The term “transparent” means that the film is transparent to the emission wavelength of the light emitting layer 10. More specifically, the term “transparent” may refer to a case where the transmittance of the emission wavelength is, e.g., 70% or more. The first conductive film 21 is continuously formed over the entire area of the front surface (the upper surface in FIG. 2) of the insulation film 4 except the opening 20, the entire area of the slant surfaces 4A of the insulation film 4 defining the opening 20 and the entire area of the front surface of the p-type guide contact layer 17 exposed from the opening 20. In other words, the first conductive film 21 is formed on the insulation film 4 to make contact with the p-type guide contact layer 17 (the p-type semiconductor layer 12) through the opening 20.

The first conductive film 21 is made of a material having properties of : (1) an electron concentration of 1×10¹⁹ cm ⁻³; (2) a transmittance of 70% or more with respect to the emission wavelength of the light emitting layer 10; and (3) a work function of 5.0 eV or more.

Examples of the material having the afore-mentioned properties include an indium oxide (In₂O₃)-based material. The first conductive film 21 may be made of ITO (Indium Tin Oxide). In this case, the contact resistance between the first conductive film 21 and the p-type semiconductor layer 12 with which the first conductive film 21 makes contact is set equal to or less than 1×10⁻³ Ω·cm². The indium oxide-based material of which the first conductive film 21 is made may include Sn at a composition ratio of 3% or more.

The second conductive film 22 is a transparent oxide film having a thickness of 400 nm or more and 600 nm or less. In other words, the transmittance of the second conductive film 22 is 70% or more with respect to the emission wavelength of the light emitting layer 10. The second conductive film 22 is formed over the entire area of the front surface (the upper surface in FIG. 2) of the first conductive film 21. The second conductive film 22 may be made of a zinc oxide (ZnO)-based material, a gallium oxide (Ga₂O₃)-based material or a tin oxide (SnO)-based material. More specifically, the second conductive film 22 is made of ZnO or MgZnO including group-III atoms of Ga or Al at a concentration of 1×10¹⁹ cm⁻³ or more. If the second conductive film 22 is made of MgZnO, the refractive index of the second conductive film 22 can be adjusted by changing the composition ratio of Mg. The composition ratio of Mg in MgZnO may be 50% or less. More specifically, MgZnO of which the second conductive film 22 is made can be represented by MgₓZn₁₋ₓO (0≦x<1).

The transparent electrode 5 serves as an upper clad layer and provides a light confinement effect by which the light emitted from the light emitting layer 10 is confined in the light emitting layer 10 between the transparent electrode 5 and the n-type clad layer 14. For that reason, the refractive index of the first conductive film 21 and the second conductive film 22 of the transparent electrode 5 is set smaller than the refractive index of the light emitting layer 10. More specifically, the refractive index of the light emitting layer 10 is 2.4. In contrast, the refractive index of the first conductive film 21 is 2.1 if the first conductive film 21 is made of ITO. The refractive index of the second conductive film 22 is 2.2 if the second conductive film 22 is made of ZnO. The refractive index of the insulation film 4 is as small as 1.4 if the insulation film 4 is made of SiO₂. Thus the insulation film 4 can provide a light confinement effect.

The light emitted from the light emitting layer 10 is confined between the transparent electrode 5 and the n-type clad layer 14. Therefore, a clad layer made of a p-type nitride semiconductor (namely, a p-type semiconductor clad layer) does not exist in the semiconductor laser device 101. In other words, the nitride semiconductor laminate structure 2 does not include any p-type semiconductor clad layer.

The n-side electrode pad 3 has a multi-layer structure formed by laminating an Al layer, a Ti layer and an Au layer in the named order from the side of the substrate 1. The Al layer makes ohmic contact with the substrate 1.

With this configuration, it is possible to provide an enhanced light confinement effect through the use of a structure having no p-type semiconductor clad layer. It is also possible to increase the oscillation efficiency, which contributes to the realization of a low threshold value (a low VF). Since the p-type semiconductor layer 12 does not include any p-type semiconductor clad layer, the distance from the transparent electrode 5 to the light emitting layer 10 is short. Accordingly, the p-type semiconductor layer 12 need not be formed into a ridge shape for the purpose of current confinement and light confinement in the transverse direction (the a-axis direction). In addition, the electric resistance grows small. If there is provided a p-type semiconductor clad layer including Al, the p-type semiconductor clad layer itself becomes a high-resistance layer. In the configuration of the present embodiment requiring no p-type semiconductor clad layer, it is possible to reduce the electric resistance. This makes it possible to realize enhanced oscillation efficiency with a simple configuration and to realize a reduced threshold value. The simple configuration requiring no ridge structure makes it possible to simplify a manufacturing process.

The nitride semiconductor laminate structure 2 includes a pair of end surfaces 24 and 25 (cleavage surfaces) formed by cleaving the c-axis direction opposite ends of the structure 2. The end surfaces 24 and 25 are parallel to each other and are perpendicular to the c-axis direction (the resonator direction). Thus a Fabry-Perrot resonator using the end surfaces 24 and 25 as resonator end surfaces is formed by the n-type guide layer 15, the light emitting layer 10 and the p-type guide contact layer 17. In other words, the light generated in the light emitting layer 10 is amplified by stimulated emission while running between the resonator end surfaces 24 and 25. A part of the light thus amplified is extracted to the outside from the resonator end surfaces 24 and 25 as laser light.

The resonator end surfaces 24 and 25 are respectively covered with insulation films (not shown). The resonator end surface 24 is an end surface lying at a plus c-axis side and the resonator end surface 25 is an end surface lying at a minus c-axis side. In other words, the crystal surface of the resonator end surface 24 is a plus c-plane and the crystal surface of the resonator end surface 25 is a minus c-plane. The insulation film formed on the minus c-plane can serve as a protective film for protecting the chemically weak minus c-plane soluble in alkali and can contribute to the improvement of reliability in the semiconductor laser device 101.

The insulation film formed to cover the resonator end surface 24 as a plus c-plane is formed of, e.g., a single ZrO₂ film. In contrast, the insulation film formed on the resonator end surface 25 as a minus c-plane is made up of multiple reflection films formed by alternately laminating, e.g., a SiO₂ film and a ZrO₂ film, more than once. The single ZrO₂ film making up the insulation film formed on the plus c-plane may have a thickness of λ/2n₁ (where λ denotes the emission wavelength of the light emitting layer 10 and n₁ stands for the refractive index of ZrO₂). On the other hand, the multiple reflection films making up the insulation film formed on the minus c-plane are formed by alternately laminating a SiO₂ film, which may have a thickness of λ/4n₂ (where n₂ signifies the refractive index of SiO₂) and a ZrO₂ film having a thickness of λ/4n₁.

With this structure, the reflectance of the resonator end surface 24 lying at the plus c-axis side becomes small and the reflectance of the resonator end surface 25 lying at the minus c-axis side becomes large. More specifically, the reflectance of the resonator end surface 24 is, e.g., about 20%, and the reflectance of the resonator end surface 25 is, e.g., about 99.5% (nearly 100%). For that reason, laser light having a larger output is emitted from the resonator end surface 24. In other words, the resonator end surface 24 serves as a laser emitting end surface in the semiconductor laser device 101.

In the configuration described above, the n-side electrode pad 3 and the transparent electrode 5 are connected to a power source. Electrons and holes are injected into the light emitting layer 10 from the n-type semiconductor layer 11 and the p-type semiconductor layer 12. Consequently, the electrons and the holes are recombined within the light emitting layer 10, thereby generating light having a wavelength of, e.g., 400 nm to 550 nm The light thus generated is confined between the n-type clad layer 14 and the transparent electrode 5 (the upper clad layer) and is propagated in the resonator direction (c-axis direction) perpendicular to the laminating direction of the nitride semiconductor laminate structure 2. More specifically, the light is amplified by stimulated emission while traveling in the c-axis direction (resonator direction) along the guide layers 15 and 17 between the resonator end surfaces 24 and 25. Then, laser light having an increased output is extracted from the resonator end surface 24 as a laser projecting end surface.

As set forth above, the semiconductor laser device 101 does not include any p-type semiconductor clad layer. In other words, the nitride semiconductor laminate structure 2 does not include any p-type semiconductor clad layer. In case where the nitride semiconductor laminate structure 2 is provided with a p-type semiconductor clad layer, the formation process of the nitride semiconductor laminate structure 2 is performed by forming the light emitting layer 10 at a relatively low temperature and then forming the p-type semiconductor clad layer at a temperature higher than the temperature at which the light emitting layer 10 is formed. It is therefore likely that, when forming the p-type semiconductor clad layer, the light emitting layer 10 suffers from thermal damage. In the present embodiment, however, the nitride semiconductor laminate structure 2 does not include any p-type semiconductor clad layer. It is therefore possible to prevent a problem of the light emitting layer 10 suffering from thermal damage in the formation process of the nitride semiconductor laminate structure 2.

In order to confine the light of the light emitting layer 10 between the transparent electrode 5 and the n-type clad layer 14, the transparent electrode 5 may need to have a large enough thickness. However, the first conductive film 21 made of an indium oxide-based material is formed at a low speed. If the transparent electrode 5 is formed of only the first conductive film 21, it becomes time-consuming to form the transparent electrode 5. On the other hand, the second conductive film 22 made of a zinc oxide-based material, a gallium oxide-based material or a tin oxide-based material is formed at a relatively high speed. However, the second conductive film 22 has a large contact resistance with respect to a p-type nitride semiconductor. In the present embodiment, the portion of the transparent electrode 5 making contact with the p-type semiconductor layer 12 (the p-type guide contact layer 17) is formed of the first conductive film 21 made of an indium oxide-based material, thereby reducing the contact resistance. In particular, since the first conductive film 21 is made of ITO, it is possible to reduce the contact resistance between the first conductive film 21 and the p-type semiconductor layer 12. The formation speed of the transparent electrode 5 can be increased by allowing the transparent electrode 5 to include the first conductive film 21 and the second conductive film 22 formed on the first conductive film 21 and made of a zinc oxide-based material, a gallium oxide-based material or a tin oxide-based material. More specifically, the first conductive film 21 is formed to have a required minimum thickness. This makes it possible to shorten the time required in forming the transparent electrode 5 and to enhance the productivity.

Inasmuch as the p-type guide contact layer 17 is made of InGaN, it is possible to form the p-type guide contact layer 17 at a low temperature as compared with a composition including Al. This makes it possible to further reduce the thermal damage to the light emitting layer 10.

The insulation film 4 is configured to insulate the p-type semiconductor layer 12 and the transparent electrode 5 in an area other than the opening 20. The insulation film 4 can perform current confinement in the opening 20. The insulation film 4 and the transparent electrode 5 as an upper clad layer contribute to the light confinement in the light emitting layer 10. Since the thickness of the insulation film 4 is 200 nm or more and 400 nm or less, the insulation film 4 can secure insulation between the p-type semiconductor layer 12 and the transparent electrode 5 in the area thereof other than the opening 20 and can enhance the effect of confining the light traveling from the p-type semiconductor layer 12 toward the transparent electrode 5.

The transparent electrode 5 serves as an electrode for supplying an electric current to the p-type semiconductor layer 12. The transparent electrode 5 extends into the opening 20 of the insulation film 4 and makes contact with the p-type semiconductor layer 12. Thus the electric connection between the transparent electrode 5 and the p-type semiconductor layer 12 is limited to the inside of the opening 20, which makes it possible to form a current confinement structure. In a typical semiconductor laser device, a current confinement structure is formed by, e.g., forming a ridge portion in the p-type semiconductor layer 12. When etching is performed to form the ridge portion, defects are generated in the semiconductor crystals existing on the side surfaces and the base of the ridge portion. Thus the device properties are likely to grow worse. In order to protect the thin ridge portion from external stresses and to prevent breakage of the device, die-bonding with respect to a mounting substrate cannot be performed in a so-called junction-down posture (a downward junction posture in which the ridge portion faces the mounting substrate). The mounting state is limited to a junction-up posture (an upward junction posture). In the present embodiment, the nitride semiconductor laminate structure 2 does not have any ridge portion. No ridge portion exists in the transparent electrode 5. The transparent electrode 5 extends into the opening 20 of the insulation film 4 and makes contact with the p-type semiconductor layer 12. Accordingly, there is no likelihood that the device properties grow worse due to the etching otherwise performed to form a ridge portion. It is also possible to take a junction-down mounting posture (a downward junction posture).

If the bonding (die-bonding) with respect to a mounting surface is performed by a junction-down method, the heat generated in the light emitting layer 10 can be dissipated from the transparent electrode 5 to the mounting substrate. This makes it possible to efficiently cool the semiconductor laser device 101 and to enhance the temperature characteristics of the semiconductor laser device 101.

In case where a ridge portion exists in the transparent electrode 5, the transparent electrode 5 may not be bonded to the mounting substrate by the junction-down method. In the semiconductor laser device 101, there is no other choice but to bond the n-side electrode pad 3 to the mounting substrate by a junction-up method. In this case, the n-side electrode pad 3 of the semiconductor laser device 101 exists in a position relatively distant from the light emitting layer 10. This makes it difficult to effectively dissipate the heat of the light emitting layer 10 to the mounting substrate lying at the side of the n-side electrode pad 3.

In addition, the opening 20 of the insulation film 4 can be formed with a relatively high accuracy. It is therefore possible to prevent the forward voltage (VF) of the semiconductor laser device 101 from varying on a device-by-device basis.

Since the first conductive film 21 includes Sn at a composition ratio of 3% or more, it is possible to increase the electric conductivity of the first conductive film 21. Inasmuch as the thickness of the first conductive film 21 is 2 nm or more and 30 nm or less, it is possible to keep the formation time of the first conductive film 21 as short as possible and to increase the formation speed of the transparent electrode 5.

Since the second conductive film 22 has a specified thickness of 400 nm or more and 600 nm or less, it is possible to enhance the light confinement effect by which light is confined between the transparent electrode 5 and the n-type clad layer 14.

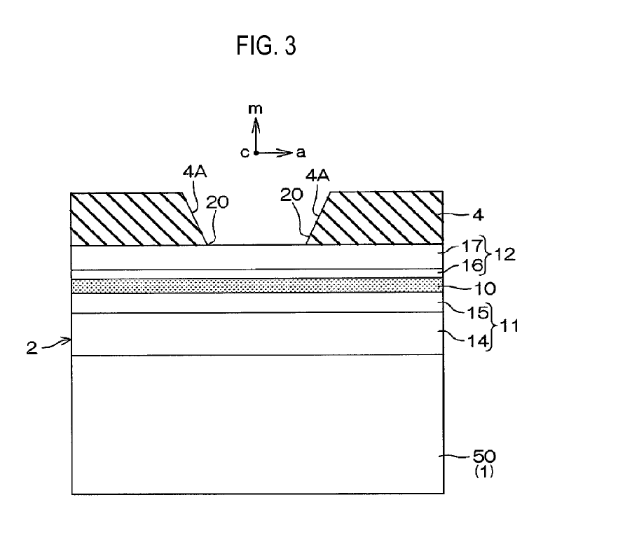

FIG. 3 is a diagrammatic section view illustrating a manufacturing method of the semiconductor laser device shown in FIG. 2.

Referring to FIG. 3, a wafer 50 is prepared first. The wafer 50 is used as the substrate 1 of the semiconductor laser device 101. The nitride semiconductor laminate structure 2 is caused to grow on the wafer 50. A resist film (not shown) having the same pattern as the opening 20 is formed on the p-type guide contact layer 17 of the nitride semiconductor laminate structure 2. Then, the insulation film 4 is formed to cover the resist film and the p-type guide contact layer 17 existing in the area where the resist film is not formed. Thereafter, a portion of the insulation film 4 and the resist film (not shown) are lifted off and patterned to thereby form the opening 20 having a stripe shape in the insulation film 4 as shown in FIG. 3. Subsequently, as shown in FIG. 2, the transparent electrode 5 is formed to make ohmic contact with the p-type guide contact layer 17 through the opening 20. Then, the n-side electrode pad 3 is formed to make ohmic contact with the substrate 1. The n-side electrode pad 3 can be formed, e.g., by resistance heating or by a metal deposition apparatus using an electron beam. The transparent electrode 5 can be formed, e.g., by a sputtering method.

The next step is to divide the wafer 50 into individual devices. In other words, the wafer 50 is cleaved in the extension direction of the opening 20 of the insulation film 4 (the c-axis direction) and in the direction perpendicular to the extension direction of the opening 20 and is diced into individual devices, each of which makes up the semiconductor laser device 101. The dividing in the direction parallel to the c-axis direction is performed along the a-plane and the dividing in the direction perpendicular to the c-axis direction is performed by cleavage along the c-plane. The resonator end surface 24 made up of the plus c-plane (cleavage surface) and the resonator end surface 25 made up of the minus c-plane (cleavage surface) are formed by the cleavage along the c-plane (see FIG. 1).

The insulation films stated above are formed on the resonator end surfaces 24 and 25 (see FIG. 1). The formation of the insulation films can be performed by an electron cyclotron resonance (ECR) method. A bar-shaped body is formed by performing the wafer dividing in the direction perpendicular to the c-axis direction (the cleavage along the c-plane). Insulation films are formed on the side surfaces (c-planes) of the bar-shaped body. Thereafter, the bar-shaped body is divided along the a-plane. Thus the step of forming the insulation films on the resonator end surfaces 24 and 25 can be simultaneously performed for a plurality of chips.

As a result, the individual semiconductor laser devices 101 (see FIGS. 1 and 2) are completely formed.

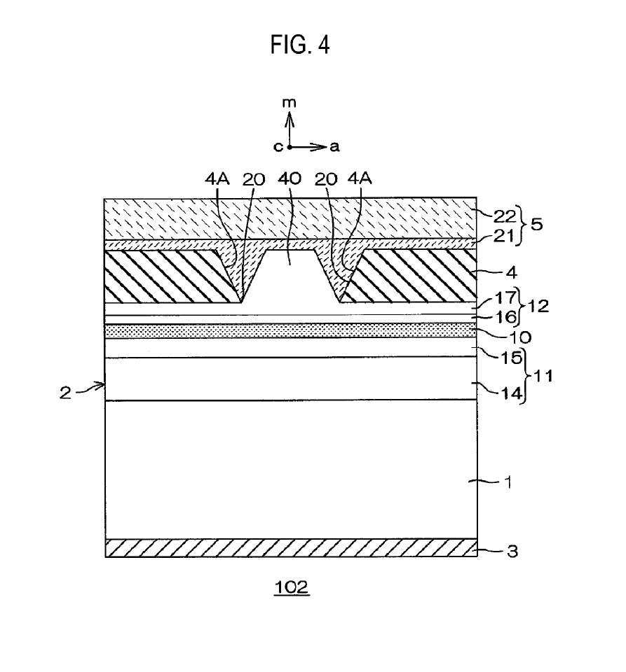

FIG. 4 is a schematic section view of a semiconductor laser device according to a second embodiment of the present disclosure, showing a cross section taken along the direction orthogonal to the resonator direction. In FIG. 4, the portions corresponding to the respective portions of the semiconductor laser device 101 of the first embodiment will be designated by like reference symbols. In the semiconductor laser device 102, when seen in a plan view, the portion of the p-type guide contact layer 17 of the p-type semiconductor layer 12 overlapping with the portion of the insulation film 4 other than the opening 20 is formed thinner than the remaining portion of the p-type guide contact layer 17 (overlapping with the opening 20). Therefore, the portion of the p-type guide contact layer 17 overlapping with the opening 20 in a plan view becomes a ridge portion (raised portion) 40 protruding toward the transparent electrode 5 and extends into the opening 20. In other words, the p-type guide contact layer 17 includes the ridge portion 40 formed into a stripe shape along the resonator direction. The cross section of the ridge portion 40 in FIG. 4 has a substantially isosceles trapezoidal shape with the width thereof getting smaller toward the transparent electrode 5. However, the cross section of the ridge portion 40 may have other shapes.

In this case, the insulation film 4 gets closer to the light emitting layer 10 because the portion of the p-type guide contact layer 17 not overlapping with the opening 20 in a plan view is formed thin. This makes it possible to enhance the current confinement effect provided by the insulation film 4. The insulation film 4 can contribute to the confinement of light in the light emitting layer 10.

In the present embodiment, the height of the ridge portion 40 is equal to or smaller than the height of the front surface of the insulation film 4. At the opposite lateral sides of the ridge portion 40, a pair of grooves having a V-like cross section is formed by the slant surfaces 4A of the insulation film 4 defining the opening 20 and by the opposite slant surfaces of the ridge portion 40. The first conductive film 21 is formed to extend into the grooves. The front surface of the first conductive film 21 is flat. The second conductive film 22 is formed on the flat front surface of the first conductive film 21. The second conductive film 22 has a flat front surface. In other words, since the height of the ridge portion 40 is equal to or smaller than the thickness of the insulation film 4, the transparent electrode 5 does not have any ridge portion. Consequently, it is possible to perform bonding by a junction-down method while employing a structure in which light confinement is enhanced by the formation of the ridge portion 40 in the p-type guide contact layer 17.

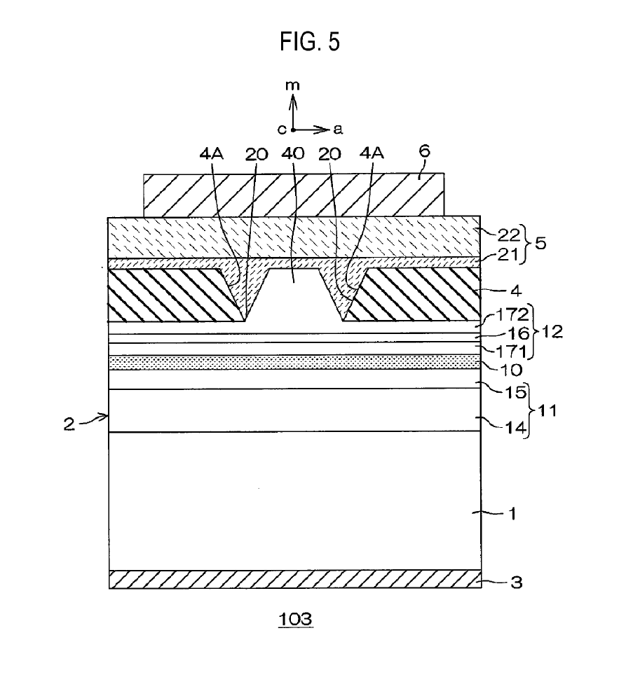

FIG. 5 is a schematic section view of a semiconductor laser device according to a third embodiment of the present disclosure, showing a cross section taken along the direction orthogonal to the resonator direction. In FIG. 5, the portions corresponding to the respective portions of the semiconductor laser device of the second embodiment (shown in FIG. 4) will be designated by like reference symbols.

The semiconductor laser device 103 includes a substrate 1, a nitride semiconductor laminate structure 2, an n-side electrode pad 3, an insulation film 4, a transparent electrode 5 as an upper clad layer, and a p-side electrode pad 6. The nitride semiconductor laminate structure 2 includes an n-type semiconductor layer 11, a light emitting layer 10 and a p-type semiconductor layer 12 which are formed on the substrate 1 in the named order. The substrate 1 may be a GaN substrate having an m-plane as a major surface. The insulation film 4 is made of, e.g., SiO₂.

The n-type semiconductor layer 11 is formed by laminating an n-type clad layer 14 and an n-type guide layer 15 in the named order from the side of the substrate 1. The light emitting layer 10 is formed on the n-type guide layer 15.

The p-type semiconductor layer 12 includes a first p-type guide layer 171 formed on the light emitting layer 10, a p-type electron block layer 16 formed on the first p-type guide layer 171 and a second p-type guide layer 172 formed on the p-type electron block layer 16. The second p-type guide layer 172 serves as a contact layer electrically connected to the transparent electrode 5. The second p-type guide layer 172 has a stripe-shaped ridge portion 40 formed along the resonator direction. The first p-type guide layer 171 is doped with Mg as a p-type impurity at a concentration of, e.g., 1×10¹⁹ cm⁻³. The thickness of the first p-type guide layer 171 is about 50 nm. The p-type electron block layer 16 is made of p-type AlGaN or AlInGaN having an Al composition ratio of 18% or more. The thickness of the p-type electron block layer 16 is about 20 nm The second p-type guide layer 172 includes a p-type impurity at a concentration higher than the concentration of the p-type impurity in the first p-type guide layer 171. More specifically, the second p-type guide layer 172 is doped with Mg as a p-type impurity at a concentration of, e.g., ×10²⁰ cm⁻³ or more (more specifically, about 1×10²⁰ cm⁻³). The second p-type guide layer 172 is formed to cover the entire area of the p-type electron block layer 16. The thickness of the ridge portion 40 of the second p-type guide layer 172 is, e.g., 10 nm or more and 50 nm or less (more specifically, about 20 nm). The total thickness of the p-type semiconductor layer 12 in the ridge portion 40 is 50 nm or more (more specifically, about 100 nm). The p-type electron block layer 16 is arranged in a position deeper than the second p-type guide layer 172 at the opposite lateral sides of the ridge portion 40. In other words, the second p-type guide layer 172 is dug down at the opposite lateral sides of the ridge portion 40 with the bottom portion thereof left.

The insulation film 4 is arranged at the opposite lateral sides of the ridge portion 40, thereby exposing the ridge portion 40 from the opening 20. In other words, the insulation film 4 makes contact with the second p-type guide layer 172 at the opposite lateral sides of the ridge portion 40.

The transparent electrode 5 is formed by laminating a first conductive film 21 and a second conductive film 22 in the named order from the side of the p-type semiconductor layer 12. The first conductive film 21 may be made of an indium oxide-based material (e.g., ITO). More specifically, the first conductive film 21 may be made of ITO (InₓSn₁₋ₓO, where 0.9≦x<1) having an indium composition ratio of 90% or more. The first conductive film 21 extends into the opening 20 and makes contact with the top surface and the opposite side surfaces of the ridge portion 40. The first conductive film 21 is formed to extend over the front surface of the insulation film 4 outside the opening 20. The second conductive film 22 may be made of a zinc oxide-based material, a gallium oxide-based material or a tin oxide-based material (e.g., ZnO) and can be formed to cover the entire area of the front surface of the first conductive film 21. The total thickness of the first conductive film 21 and the second conductive film 22 (namely, the thickness of the transparent electrode 5) may be 400 nm or more (e.g., about 600 nm).

The p-side electrode pad 6 is a metal electrode making ohmic contact with the transparent electrode 5 and may be, e.g., a laminated electrode film formed by laminating a Ti layer and an Au layer one above the other on the front surface of the transparent electrode 5. The width of the p-side electrode pad 6 in the resonator intersecting direction (the left-right direction “a” shown in FIG. 5) orthogonal to the resonator direction and the laminating direction of the nitride semiconductor laminate structure 2 is smaller than the width of the transparent electrode 5. In other words, the width of the second conductive film 22 in the resonator intersecting direction is larger than the width of the p-side electrode pad 6 in the resonator intersecting direction.

In the semiconductor laser device 103 configured as above, the first and second conductive films 21 and 22 serve as an upper clad layer and contribute to the light confinement in the light emitting layer 10. The first conductive film 21 made of an indium oxide-based material has a low contact resistance with respect to the p-type nitride semiconductor. The second conductive film 22 made of a zinc oxide-based material, a gallium oxide-based material or a tin oxide-based material shows a high growth rate. Accordingly, the transparent electrode 5 made up of the first and second conductive films 21 and 22 has a low contact resistance with respect to the p-type semiconductor layer 12 and can be formed into a necessary thickness for light confinement within a short period of time.

In the semiconductor laser device 103 of the present embodiment, the p-type semiconductor layer 12 includes the p-type electron block layer 16 made of p-type AlGaN or p-type AlInGaN having an Al composition ratio of 18% or more. Thus the p-type semiconductor layer 12 can reflect electrons toward the light emitting layer 10 and can increase the efficiency of electron injection to the light emitting layer 10. The stripe-shaped ridge portion 40 extending in the resonator direction is formed in the p-type semiconductor layer 12. The first conductive film 21 makes contact with the ridge portion 40. The insulation film 4 is arranged at the opposite lateral sides of the ridge portion 40 to make contact with the p-type semiconductor layer 12. It is therefore possible to form a current confinement structure. Moreover, the insulation film 4 low in refractive index than the p-type semiconductor layer 12 can be arranged nearer to the light emitting layer 10. Thus the light confinement in the light emitting layer 10 in the resonator intersecting direction (the left-right direction “a” shown in FIG. 5) gets enhanced. In other words, the light confinement in the vertical direction (the laminating direction of the nitride semiconductor laminate structure 2) can be enhanced by setting the thickness of the p-type semiconductor layer 12 in the ridge portion 40 equal to or larger than 50 nm. At the same time, the light confinement in the horizontal direction can be enhanced by arranging the insulation film 4 nearer to the light emitting layer 10. This can contribute to the reduction of an oscillation threshold value.

The p-type electron block layer 16 is arranged within the p-type semiconductor layer 12 in a position deeper than the front surface of the p-type semiconductor layer 12 at the opposite lateral sides of the ridge portion 40. The p-type electron block layer 16 is opposed to the entire area of the light emitting layer 10. This makes it possible to increase the efficiency of electron injection to the light emitting layer 10.

In the semiconductor laser device 103 of the present embodiment, the p-type semiconductor layer 12 includes the first p-type guide layer 171 formed on the light emitting layer 10 and the second p-type guide layer 172 formed on the first p-type guide layer 171. The first p-type guide layer 171 and the second p-type guide layer 172 contribute to the carrier confinement and the light confinement in the light emitting layer 10. The second p-type guide layer 172 plays the role of a contact layer making contact with the first conductive film 21. The second p-type guide layer 172 has a thickness of 10 nm or more and 50 nm or less in the ridge portion 40 and, therefore, can provide a carrier confinement effect and a light confinement effect. The second p-type guide layer 172 is doped with a p-type impurity (e.g., Mg) at a concentration of 1×10²⁰ cm ⁻³ or more. This reduces the contact resistance between the second p-type guide layer 172 and the first conductive film 21. However, the p-type nitride semiconductor layer doped with a p-type impurity at a concentration of 1×10²⁰ cm⁻³ or more has an increased electric resistance. In view of this, the thickness of the p-type nitride semiconductor layer 12 is set equal to or smaller than 50 nm, thereby reducing the series resistance. This makes it possible to reduce the series resistance of the semiconductor laser device 103 and to restrain heat generation in the semiconductor laser device 103, which contributes to the reduction of an oscillation threshold value. The lower limit value of the thickness of the nitride semiconductor layer required to dope the nitride semiconductor layer with a p-type impurity (e.g., Mg) at a concentration of 1×10²⁰ cm⁻³ or more is 10 nm.

If the second p-type guide layer 172 is formed to have a thickness of 50 nm, a width of 2 μm and a length (resonator length) of 30 μm in the ridge portion 40 and if the doping concentration of a p-type impurity (e.g., Mg) in the second p-type guide layer 172 is 1×10²⁰ cm⁻³ or more, the electric resistance in the second p-type guide layer 172 can be made equal to or smaller than 8 Ω.

In the semiconductor laser device 103 of the present embodiment, the p-side electrode pad 6 is smaller in width than the second conductive film 22. Thus the etching can be stopped in the second conductive film 22 when patterning the p-side electrode pad 6. In other words, the p-side electrode pad 6 can be patterned by using the second conductive film 22 as an etching stopper. For example, if the p-side electrode pad 6 has an Au film, the process for forming the p-side electrode pad 6 includes a step of forming an Au film (electrode pad film) and a step of patterning the Au film by dry etching (e.g., reactive ion etching). In this case, the second conductive film 22 made of a zinc oxide-based material, a gallium oxide-based material or a tin oxide-based material (e.g., ZnO) is resistant to the reactive ion etching performed with respect to Au. Thus the etching of the Au film is stopped in the second conductive film 22. In a hypothetical case where the base film existing under the electrode pad film is the insulation film 4 (e.g., a silicon oxide film), it is sometimes the case that the insulation film 4 has no resistance to the etching performed with respect to the electrode pad film. In this case, it is likely that, when etching the electrode pad film, the insulation film 4 is etched and the p-type semiconductor layer 12 is exposed. If the p-type semiconductor layer 12 is exposed, there is a likelihood that, when an attempt is made to mount the semiconductor laser device 103 on a substrate by a junction-down method, a brazing material such as a solder or the like may come into contact with the p-type semiconductor layer 12 to thereby form an undesired current path. The configuration of the present embodiment, on the other hand, allows for the etching of the electrode pad film to be stopped by the second conductive film 22. This makes it possible to avoid the problem of the p-type semiconductor layer 12 being exposed and to restrain or prevent formation of an undesired current path.

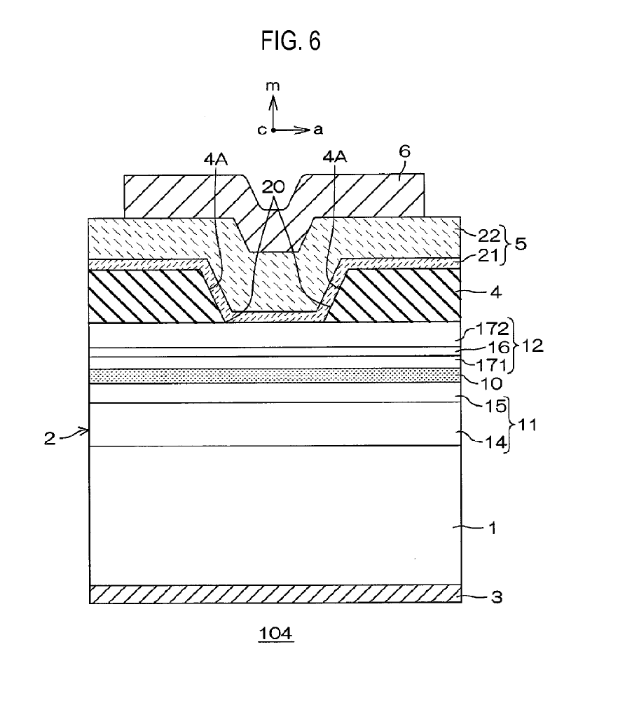

FIG. 6 is a schematic section view of a semiconductor laser device according to a fourth embodiment of the present disclosure, showing a cross section taken along the direction orthogonal to the resonator direction. In FIG. 6, the portions corresponding to the respective portions of the semiconductor laser device of the third embodiment (shown in FIG. 5) will be designated by like reference symbols.

The semiconductor laser device 104 has the same configuration as the semiconductor laser device 103 of the third embodiment except that the ridge portion 40 is not formed in the p-type semiconductor layer 12. In other words, the second p-type guide layer 172 is formed into a uniform thickness of 10 nm or more and 50 nm or less. In order to have the insulation film 4 come closer to the light emitting layer 10 and to sufficiently perform the light confinement in the resonator intersecting direction (horizontal direction), the total thickness of the p-type semiconductor layer 12 may be less than 50 nm With this configuration, it is equally possible to provide the same technical effects as provided by the configuration of the third embodiment.

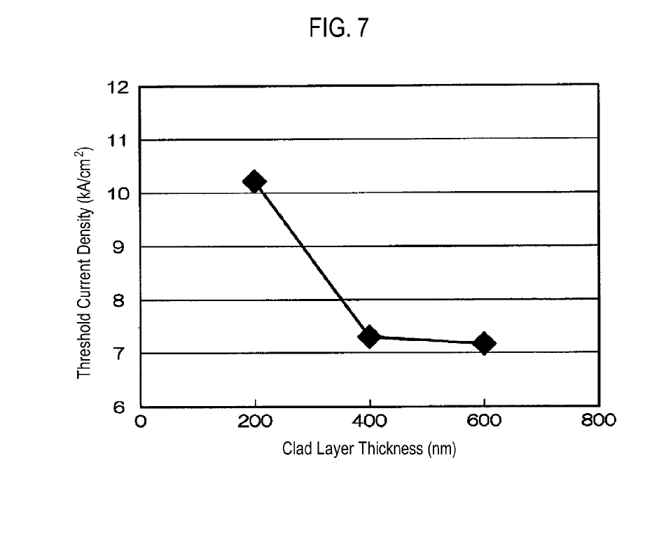

FIG. 7 represents the investigation results on the relationship between the thickness of the transparent electrode 5 as an upper clad layer and the threshold current density. It can be appreciated that, as the transparent electrode 5 becomes thicker, the light confinement grows stronger and the threshold current density grows lower. If the thickness of the transparent electrode 5 is in a range of 400 nm or more, the threshold current gets saturated. Accordingly, it is desirable that the transparent electrode 5 be formed to have a thickness of 400 nm or more (namely, such that the lower limit value of the thickness becomes equal to 400 nm). By setting the total thickness of the first and second conductive films 21 and 22 (the thickness of the transparent electrode 5) equal to or larger than 400 nm in this manner, it is possible to enable the first and second conductive films 21 and 22 (the transparent electrode 5) to have a high enough light confinement function.

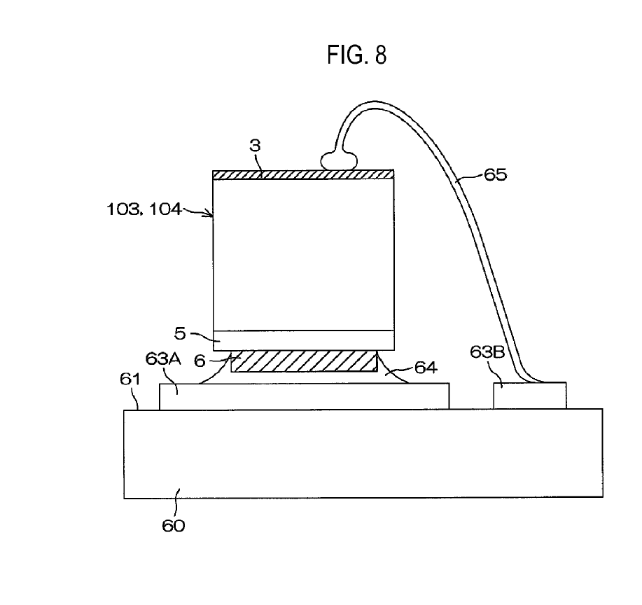

FIG. 8 is a diagrammatic section view showing a structure in which the semiconductor laser device 103 or 104 is bonded to a sub-mount by a junction-down method. Wiring patterns 63A and 63B insulated from each other are formed on a device mount surface 61 of a sub-mount substrate 60. The p-side electrode pad 6 is bonded to one wiring pattern 63A by brazing material 64 such as solder or the like. In other words, the semiconductor laser device 103 or 104 is bonded to the sub-mount substrate 60 by a junction-down method with the p-side electrode pad 6 facing the device mount surface 61 of the sub-mount substrate 60. The n-side electrode pad 3 is connected to the wiring pattern 63A by a bonding wire 65.

With this configuration, it is possible to provide the semiconductor laser device 103 or 104 mounted on the sub-mount substrate 60 by a so-called junction-down method. This makes it possible to dissipate heat through the sub-mount substrate 60 and to increase the oscillation efficiency of the semiconductor laser device 103 or 104. Since the p-side electrode pad 6 is smaller in width than the second conductive film 22, it is possible to restrain the brazing material 64 such as solder or the like from flowing out from the area of the nitride semiconductor laminate structure 2. This makes it possible to restrain generation of any connection defect such as a short circuit.

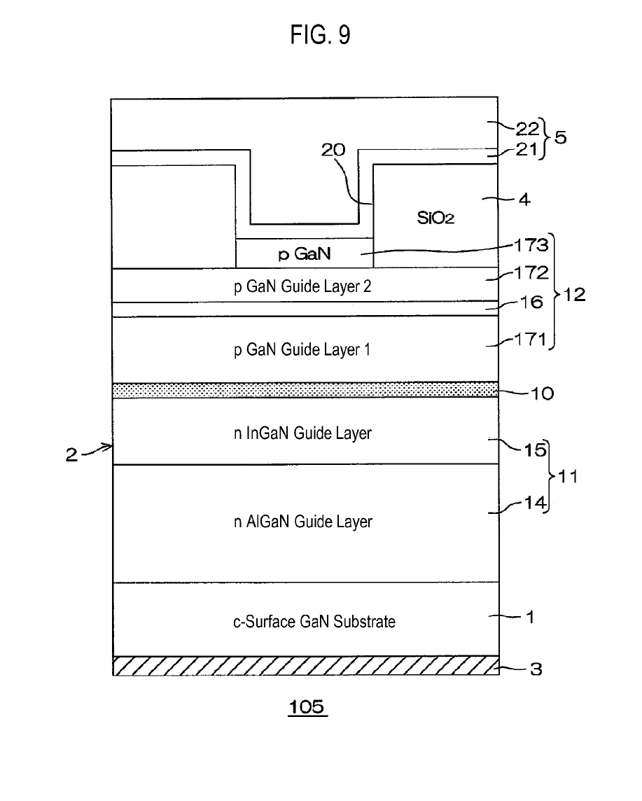

FIG. 9 is a schematic section view of a semiconductor laser device according to a fifth embodiment of the present disclosure, showing a cross section taken along the direction orthogonal to the resonator direction. In FIG. 9, the portions corresponding to the respective portions of the semiconductor laser device 101 of the first embodiment will be designated by like reference symbols.

The semiconductor laser device 105 includes a substrate 1, a nitride semiconductor laminate structure 2, an n-side electrode pad 3, an insulation film 4 and a transparent electrode 5 as an upper clad layer. The nitride semiconductor laminate structure 2 includes an n-type semiconductor layer 11, a light emitting layer 10 and a p-type semiconductor layer 12, which are laminated on the substrate 1 in the named order. The substrate 1 may be a GaN substrate having a c-plane as a major surface. The insulation film 4 is made of, e.g., SiO₂.

The n-type semiconductor layer 11 is formed by laminating an n-type clad layer 14 and an n-type guide layer 15 in the named order from the side of the substrate 1. The light emitting layer 10 is formed on the n-type guide layer 15. For example, the n-type clad layer 14 may be an n-type AlGaN layer and the n-type guide layer 15 may be an n-type InGaN layer.

The p-type semiconductor layer 12 includes a first p-type guide layer 171 formed on the light emitting layer 10, a p-type electron block layer 16 formed on the first p-type guide layer 171, a second p-type guide layer 172 formed on the p-type electron block layer 16 and a p-type contact layer 173 formed on the second p-type guide layer 172. The p-type contact layer 173 makes up a stripe-shaped ridge portion extending along the resonator direction. In other words, the p-type contact layer 173 is formed into a stripe shape and is cut down to the second p-type guide layer 172 at the opposite sides in the resonator intersecting direction.

The first p-type guide layer 171 is doped with Mg as a p-type impurity at a concentration of, e.g., 5×10¹⁸ cm ⁻³ or more and 5×10¹⁹ cm⁻³ or less. The thickness of the first p-type guide layer 171 is about 40 nm The first p-type guide layer 171 may be a p-type GaN layer. The p-type electron block layer 16 is made of p-type AlGaN or p-type AlInGaN having an Al composition ratio of 18% to 22%. The thickness of the p-type electron block layer 16 is about 20 nm The second p-type guide layer 172 includes a p-type impurity at a concentration of 5×10¹⁸ cm⁻³ or more and 5×10¹⁹ cm⁻³ or less, which is higher than the concentration of the p-type impurity in the first p-type guide layer 171. The second p-type guide layer 172 may be a p-type GaN layer. The second p-type guide layer 172 is formed to cover the entire area of the p-type electron block layer 16 and is formed into a thickness of, e.g., 50 nm or less. The p-type contact layer 173 is formed of, e.g., a p-type GaN layer, and is doped with Mg as a p-type impurity at a concentration higher than the concentration of the p-type impurity in the second p-type guide layer 172. For example, the concentration of the p-type impurity (Mg) in the p-type contact layer 173 may be 1×10²⁰ cm ⁻³ or more. The thickness of the p-type contact layer 173 may be about 30 nm In order to reduce the thickness of the device, the p-type semiconductor layer 12 may be formed to have a total thickness of 1500 Å or less in the position of the p-type contact layer 173 making up a ridge portion.

The insulation film 4 is arranged at the opposite lateral sides of the p-type contact layer 173 making up a ridge portion such that the top surface of the p-type contact layer 173 is exposed from the opening 20. In other words, the insulation film 4 makes contact with the second p-type guide layer 172 at the opposite lateral sides of the p-type contact layer 173 having a ridge shape.

The transparent electrode 5 is formed by laminating a first conductive film 21 and a second conductive film 22 in the named order from the side of the p-type semiconductor layer 12. The first conductive film 21 is made of an indium oxide-based material (e.g., ITO). The first conductive film 21 extends into the opening 20 and makes contact with the p-type contact layer 173. The first conductive film 21 is formed to extend over the front surface of the insulation film 4 outside the opening 20. The second conductive film 22 is made of a zinc oxide-based material, a gallium oxide-based material or a tin oxide-based material (e.g., ZnO) and is formed to cover the entire area of the front surface of the first conductive film 21.

In the semiconductor laser device 105 configured as above, the first and second conductive films 21 and 22 serve as an upper clad layer and contribute to the light confinement in the light emitting layer 10. The first conductive film 21 made of an indium oxide-based material has a low contact resistance with respect to the p-type nitride semiconductor. The second conductive film 22 made of a zinc oxide-based material, a gallium oxide-based material or a tin oxide-based material shows a high growth rate. Accordingly, the transparent electrode 5 made up of the first and second conductive films 21 and 22 has a low contact resistance with respect to the p-type semiconductor layer 12 and can be formed into a necessary thickness for light confinement within a short period of time.

In the semiconductor laser device 105 of the present embodiment, the p-type semiconductor layer 12 includes the p-type electron block layer 16 arranged between the first and second p-type guide layers 171 and 172. This makes it possible to reflect electrons toward the light emitting layer 10 and to increase the efficiency of electron injection to the light emitting layer 10. The first and second p-type guide layers 171 and 172 arranged to interpose the p-type electron block layer 16 therebetween contribute to the carrier confinement and the light confinement in the light emitting layer 10. The p-type contact layer 173 is high in the p-type impurity concentration thereof. Thus the contact resistance between the p-type contact layer 173 and the second conductive film 22 is kept low. The second p-type guide layer 172 is lower in the p-type impurity concentration than the p-type contact layer 173. The first p-type guide layer 171 is lower in the p-type impurity concentration than the second p-type guide layer 172. In other words, the p-type impurity concentration grows lower toward the light emitting layer 10, in which structure the absorption of light by the impurity is restrained.

Since the p-type contact layer 173 makes up a stripe-shaped ridge portion, there is provided a current confinement structure in which an electric current is concentrated on the ridge portion. The insulation film 4 is arranged at the opposite lateral sides of the ridge portion. Therefore, the light confinement in the vertical direction can be performed by securing, to some extent, the thickness of the p-type semiconductor layer 12 including the p-type contact layer 173. At the same time, the light confinement in the horizontal direction can be enhanced by arranging the insulation film 4 nearer to the light emitting layer 10. This makes it possible to reduce the oscillation threshold value. In particular, if the thickness of the second p-type guide layer 172 is set equal to or smaller than 50 nm, the insulation film 4 existing at the opposite lateral sides of the ridge portion can be arranged nearer to the light emitting layer 10. This makes it possible to further enhance the light confinement in the horizontal direction, which can contribute to the reduction of the oscillation threshold value.

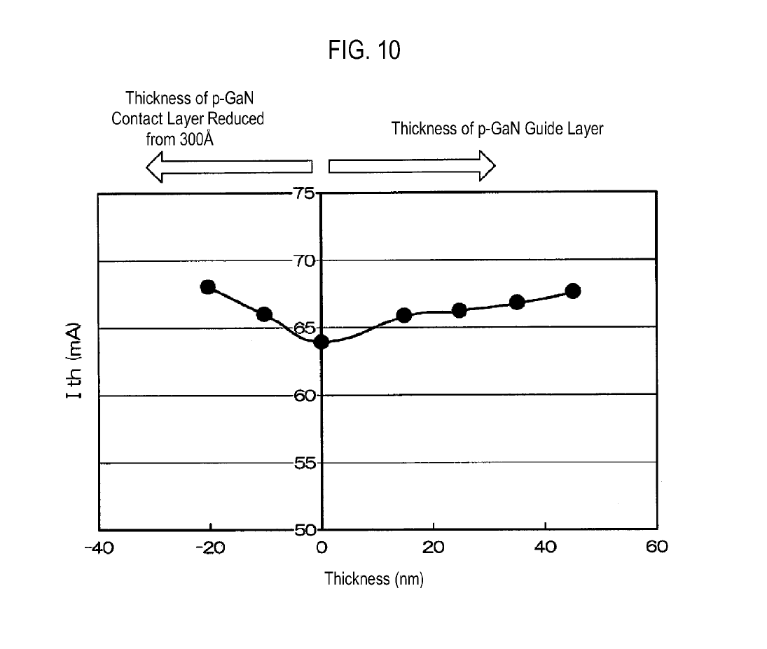

FIG. 10 represents the results from analyzing a relationship between the thickness of a p-type GaN contact layer and a second p-type GaN guide layer versus a threshold current. If the threshold current of the semiconductor laser device 105 is measured while gradually reducing the thickness of the p-type GaN contact layer 173 from 30 nm, it can be noted that the threshold current is increased with the reduction of the thickness of the p-type GaN contact layer 173. In other words, for the purpose of light confinement, it is necessary for the p-type GaN contact layer 173 to have a certain degree of thickness. On the other hand, if the threshold current of the semiconductor laser device 105 is measured while gradually increasing the thickness of the second p-type GaN guide layer 172 from 0 nm, it can be noted that the threshold current is increased with the increase of the thickness of the second p-type GaN guide layer 172. Accordingly, the threshold current can be reduced by setting the thickness of the second p-type GaN guide layer 172 as small as possible, arranging the insulation film 4 nearer to the light emitting layer 10 and enhancing the light confinement in the horizontal direction. More specifically, the thickness of the second p-type GaN guide layer 172 may be set equal to or smaller than 50 nm This makes it possible to reduce the threshold current.

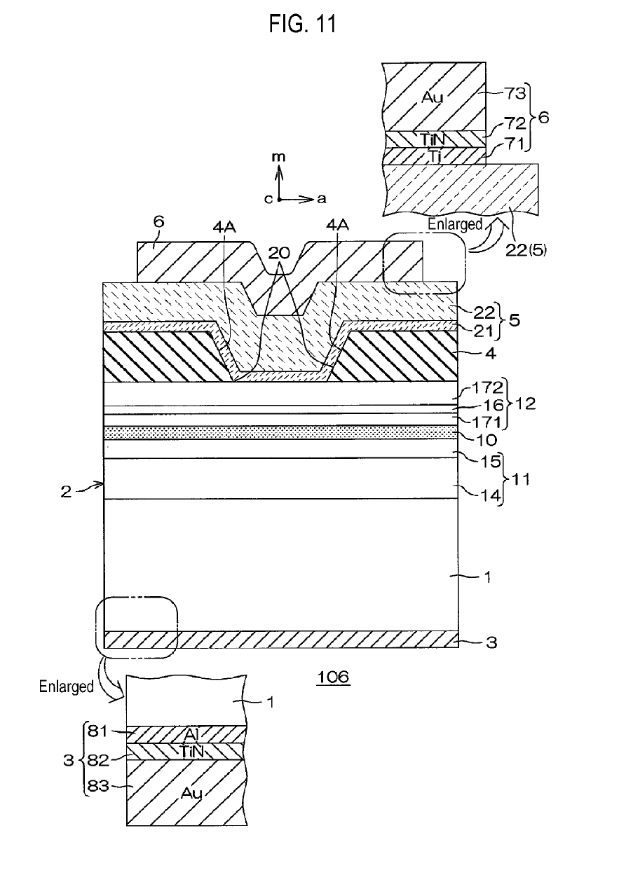

FIG. 11 is a schematic section view of a semiconductor laser device according to a sixth embodiment of the present disclosure, showing a cross section taken along the direction orthogonal to the resonator direction. In FIG. 11, there are also shown the structures of a p-side electrode pad and an n-side electrode pad as enlarged views. In FIG. 11, the portions corresponding to the respective portions of the semiconductor laser device 104 of the fourth embodiment (shown in FIG. 6) will be designated by like reference symbols.

The semiconductor laser device 106 includes a substrate 1, a nitride semiconductor laminate structure 2, an n-side electrode pad 3, an insulation film 4, a transparent electrode 5 as an upper clad layer, and a p-side electrode pad 6. The nitride semiconductor laminate structure 2 includes an n-type semiconductor layer 11, a light emitting layer 10 and a p-type semiconductor layer 12, which are laminated on the substrate 1 in the named order. The substrate 1 may be a GaN substrate having an m-plane as a major surface. The insulation film 4 is made of, e.g., SiO₂.

The n-type semiconductor layer 11 is formed by laminating an n-type clad layer 14 and an n-type guide layer 15 in the named order from the side of the substrate 1. The light emitting layer 10 is formed on the n-type guide layer 15.

The p-type semiconductor layer 12 includes a first p-type guide layer 171 formed on the light emitting layer 10, a p-type electron block layer 16 formed on the first p-type guide layer 171 and a second p-type guide layer 172 formed on the p-type electron block layer 16. The second p-type guide layer 172 serves as a contact layer electrically connected to the transparent electrode 5.

The insulation film 4 has an opening 20 formed into a stripe shape to extend along the resonator direction. The front surface of the second p-type guide layer 172 is exposed in a stripe shape from the opening 20. In other words, the insulation film 4 makes contact with the second p-type guide layer 172 at the opposite lateral sides of the opening 20.

The transparent electrode 5 is formed by laminating a first conductive film 21 and a second conductive film 22 in the named order from the side of the p-type semiconductor layer 12. The first conductive film 21 is made of an indium oxide-based material (e.g., ITO). The first conductive film 21 extends into the opening 20 and makes contact with the second p-type guide layer 172. The first conductive film 21 is formed to extend over the front surface of the insulation film 4 outside the opening 20. The second conductive film 22 is made of a zinc oxide-based material, a gallium oxide-based material or a tin oxide-based material (e.g., ZnO) and is formed to cover the entire area of the front surface of the first conductive film 21. The transparent electrode 5 has a transmittance of 80% or more with respect to the light having the oscillation wavelength of the semiconductor laser device 107. The transparent electrode 5 is made of a material other than a nitride semiconductor. The resistivity of the transparent electrode 5 is 1×10⁻³ Ω·cm or less.

The p-side electrode pad 6 is a metal electrode making ohmic contact with the transparent electrode 5 and may be, e.g., a laminated electrode film formed by laminating a Ti layer 71, a TiN layer 72 and an Au layer 73 on the front surface of the transparent electrode 5 in the named order. The Ti layer 71 and the TiN layer 72 may be formed by a sputtering method continuously performed within one and same chamber. The Au layer 73 may be formed by a vapor deposition method.

The n-side electrode pad 3 is a metal electrode making ohmic contact with the substrate 1 and may be, e.g., a laminated electrode film formed by laminating an Al layer 81, a TiN layer 82 and an Au layer 83 in the named order from the side of the substrate 1.

In the semiconductor laser device 106 configured as above, the first and second conductive films 21 and 22 serve as an upper clad layer and contribute to the light confinement in the light emitting layer 10. The first conductive film 21 made of an indium oxide-based material has a low contact resistance with respect to the p-type nitride semiconductor. The second conductive film 22 made of a zinc oxide-based material, a gallium oxide-based material or a tin oxide-based material shows a high growth rate. Accordingly, the transparent electrode 5 made up of the first and second conductive films 21 and 22 has a low contact resistance with respect to the p-type semiconductor layer 12 and can be formed into a necessary thickness for light confinement within a short period of time.

In the present embodiment, the p-side electrode pad 6 formed to make contact with the second conductive film 22 includes TiN (titanium nitride). More specifically, the p-side electrode pad 6 is a laminated electrode film formed by laminating the Ti layer 71, the TiN layer 72 and the Au layer 73 in the named order from the side of the second conductive film 22. The TiN layer 72 of the laminated electrode film serves to restrain diffusion of oxygen atoms from the second conductive film 22 when a half-finished device is subjected to heat treatment in the manufacturing process. This makes it possible to retrain or prevent the p-side electrode pad 6 from being highly resistant or being peeled off. In order to bring the n-side electrode pad 3 into ohmic contact with the substrate 1, it is sometimes necessary to subject a half-finished device to heat treatment (sintering) at a temperature of, e.g., 400 degrees C. to 900 degrees C. Even after going through the heat treatment, the p-side electrode pad 6 including the TiN layer 72 can be kept at a low resistance. It is also possible to keep the strong adherence of the p-side electrode pad 6 to the nitride semiconductor laminate structure 2.

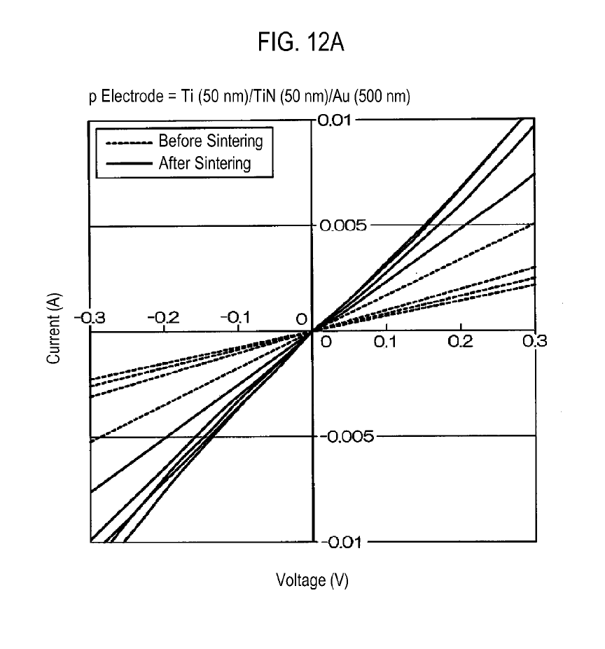

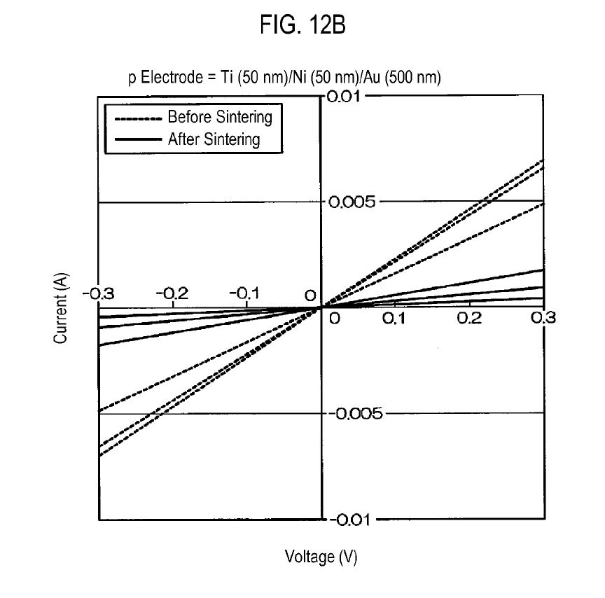

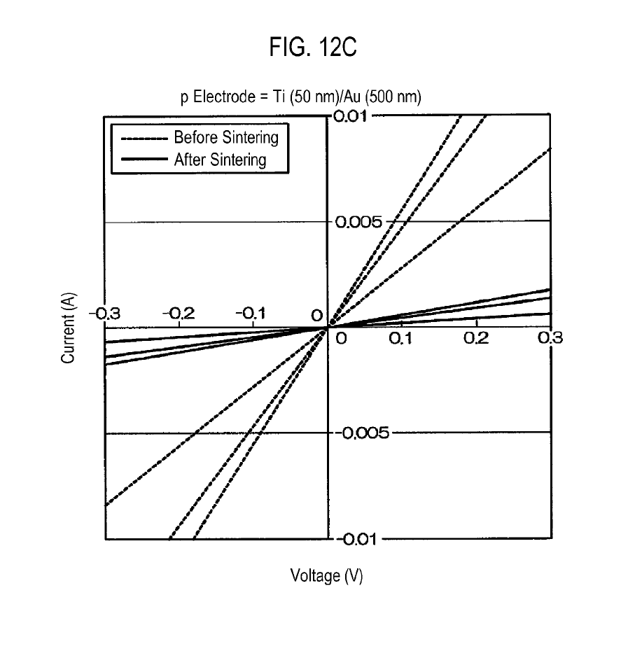

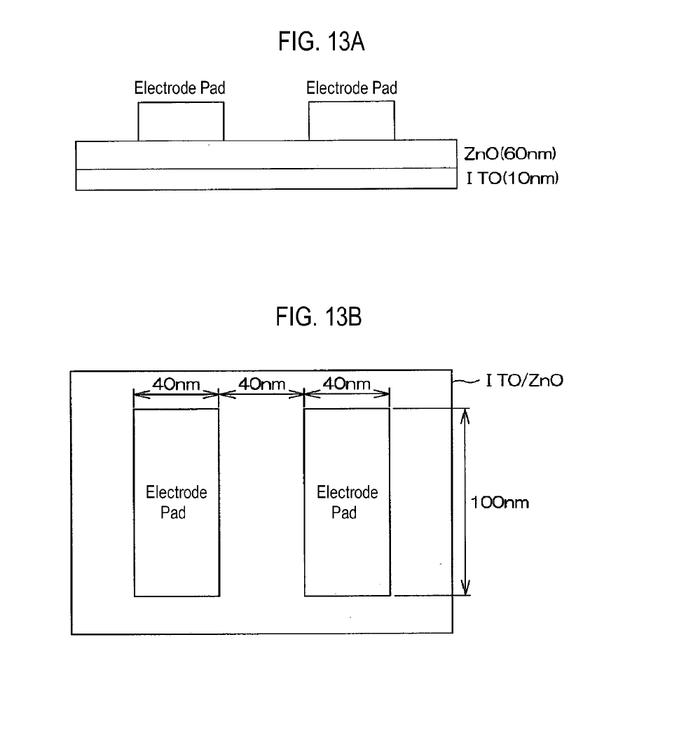

FIGS. 12A, 12B and 12C represent the measurement results of the resistance characteristics of electrode pads formed on a ZnO film and made of a laminated electrode film. The measurement was conducted using a measurement specimen prepared by forming a ZnO film (having a thickness of 60 nm) on an ITO film (having a thickness of 10 nm) and forming a pair of electrode pads on the surface of the ZnO film as shown in FIG. 13A, a section view, and FIG. 13B, a plan view. The electrode pads are formed into a rectangular shape to have a size of 40 μm (short side)×100 μm (long side). The electrode pads are arranged so that the long sides thereof can face each other in a parallel relationship with a gap of 40 μm left therebetween. The measurement results of an electric current flowing between the electrode pads when a voltage is applied to between the electrode pads are shown in FIGS. 12A, 12B and 12C. The measurement was conducted before and after the heat treatment (sintering). The heat treatment was performed at a temperature of about 600 degrees C. FIG. 12A shows the measurement results when each of the electrode pads is made up of a laminated electrode film formed by laminating a Ti film (having a thickness of 50 nm), a TiN film (having a thickness of 50 nm) and an Au film (having a thickness of 500 nm) in the named order from the front surface of the ZnO film (a working example). FIG. 12B shows the measurement results when each of the electrode pads is made up of a laminated electrode film formed by laminating a Ti film (having a thickness of 50 nm), an Ni film (having a thickness of 50 nm) and an Au film (having a thickness of 500 nm) in the named order from the front surface of the ZnO film (a comparative example). FIG. 12C shows the measurement results when each of the electrode pads is made up of a laminated electrode film formed by laminating a Ti film (having a thickness of 50 nm) and an Au film (having a thickness of 500 nm) in the named order from the front surface of the ZnO film (a comparative example).

In the comparative examples shown in FIGS. 12B and 12C, the electric resistance is higher after the heat treatment than before the heat treatment. This may be due to the electric resistance of the electrode pads being increased by the diffusion of oxygen atoms existing in the ZnO film. In the working example shown in FIG. 12A, the electric resistance is lower after the heat treatment than before the heat treatment. Thus the electrode pads have good resistance characteristics. This may be due to the diffusion of oxygen atoms being restrained by the TiN film of each of the electrode pads.

In this manner, the p-side electrode pad 6 making contact with the second conductive film 22 made of a zinc oxide-based material, a gallium oxide-based material or a tin oxide-based material is configured to include TiN, particularly a TiN layer. This makes it possible to improve the resistance characteristics.

In addition to the Ti/TiN/Au laminated electrode film, a single TiN film, a laminated electrode film formed by laminating a TiN layer and an Au layer in the named order from the front surface of the second conductive film 22 or a laminated electrode film formed by laminating a TiN layer and an Al layer in the named order from the front surface of the second conductive film 22 can be used as the p-side electrode pad 6.

As the n-side electrode pad 3, it is possible to use a single TiN film, a laminated electrode film formed by laminating an Al layer and a TiN layer in the named order from the side of the nitride semiconductor laminate structure 2 and a laminated electrode film formed by laminating a TiN layer and an Au layer in the named order from the side of the nitride semiconductor laminate structure 2. In addition, a laminated electrode film formed by laminating a Ti layer and an Al layer in the named order from the front surface of the substrate 1 or a single Al film can be used as the n-side electrode pad 3. Moreover, a laminated electrode film formed by laminating an Al contact metal layer, a Ni layer and an Au layer in the named order from the side of the nitride semiconductor laminate structure 2 can be used as the n-side electrode pad 3. In addition, a laminated electrode film including an Al contact metal layer, a Pt layer and an Au layer may be used as the n-side electrode pad 3. Sintering needs to be performed in case of using Al.

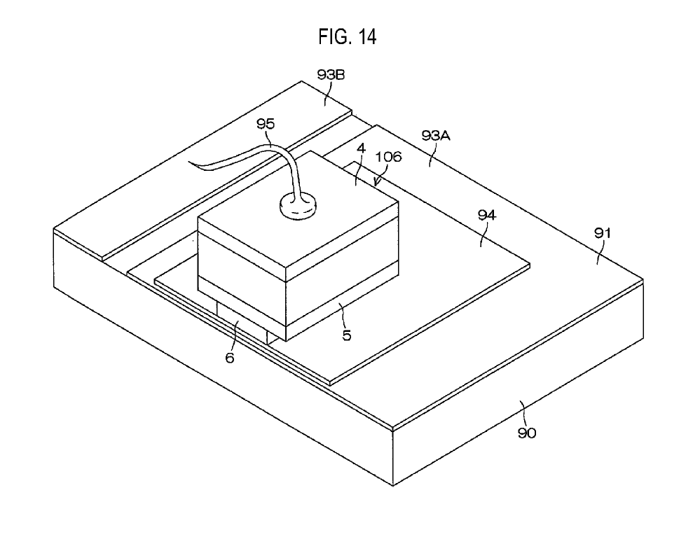

FIG. 14 is a diagrammatic perspective view showing a structure in which the semiconductor laser device 106 is bonded to a sub-mount by a junction-down method. Wiring patterns 93A and 93B insulated from each other are formed on a device mount surface 91 of a sub-mount substrate 90. The p-side electrode pad 6 is bonded to the wiring pattern 93A by brazing material 94 such as Au-Sn alloy or the like. In other words, the semiconductor laser device 106 is bonded to the sub-mount substrate 90 by a junction-down method with the p-side electrode pad 6 facing the device mount surface 91 of the sub-mount substrate 90. The n-side electrode pad 3 is connected to the wiring pattern 93B by a bonding wire 95 such as an Au wire. The sub-mount substrate 90 is made of, e.g., AlN. Each of the wiring patterns 93A and 93B is made up of, e.g., a laminated metal film formed by laminating a Ti layer, a Pt layer and an Au layer in the named order from the device mount surface 91.

With this configuration, it is possible to provide the semiconductor laser device 106 mounted on the sub-mount substrate 90 by a so-called junction-down method. This makes it possible to dissipate heat through the sub-mount substrate 90 and to increase the oscillation efficiency of the semiconductor laser device 106. Since the p-side electrode pad 6 includes TiN, it is possible to prevent oxygen atoms in the second conductive film 22 from being diffused into the p-side electrode pad 6 under the influence of heat generated during an operation and consequently increasing the resistance value. It is also possible to prevent the p-side electrode pad 6 from being peeled off.

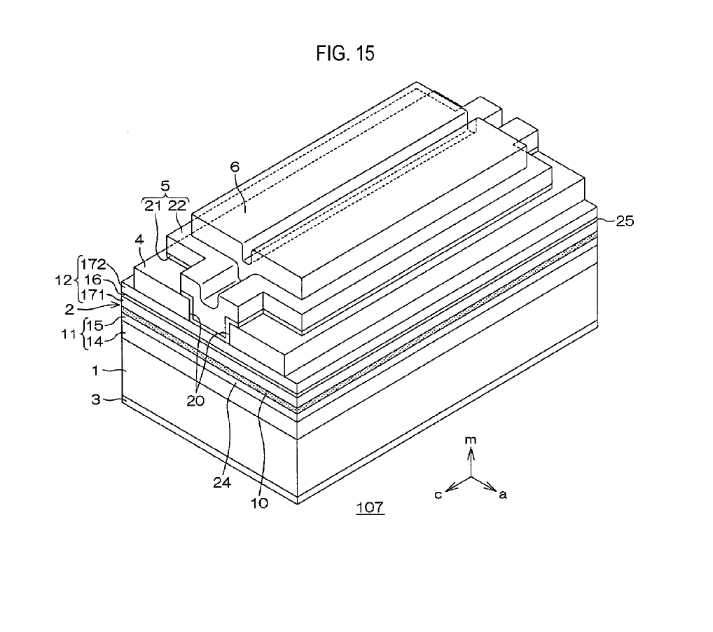

FIG. 15 is a schematic perspective view of a semiconductor laser device according to a seventh embodiment of the present disclosure. In FIG. 15, the portions corresponding to the respective portions of the semiconductor laser device 106 of the sixth embodiment (shown in FIG. 11) will be designated by like reference symbols.

The semiconductor laser device 107 includes a substrate 1, a nitride semiconductor laminate structure 2, an n-side electrode pad 3, an insulation film 4, a transparent electrode 5 as an upper clad layer, and a p-side electrode pad 6. The nitride semiconductor laminate structure 2 includes an n-type semiconductor layer 11, a light emitting layer 10 and a p-type semiconductor layer 12, which are formed on the substrate 1 in the named order. The substrate 1 may be a GaN substrate having an m-plane as a major surface. The insulation film 4 is made of, e.g., SiO₂.

The n-type semiconductor layer 11 is formed by laminating an n-type clad layer 14 and an n-type guide layer 15 in the named order from the side of the substrate 1. The light emitting layer 10 is formed on the n-type guide layer 15.

The p-type semiconductor layer 12 includes a first p-type guide layer 171 formed on the light emitting layer 10, a p-type electron block layer 16 formed on the first p-type guide layer 171 and a second p-type guide layer 172 formed on the p-type electron block layer 16. The second p-type guide layer 172 serves as a p-type contact layer electrically connected to the transparent electrode 5. The second p-type guide layer 172 serving as a p-type contact layer may be doped with a p-type impurity (e.g., Mg) at a concentration of 1×10²⁰ cm ⁻³ or more. This makes it possible to reduce the contact resistance between the first conductive film 21 and the p-type semiconductor layer 12, thereby providing a semiconductor laser device having a low series resistance.

The insulation film 4 has an opening 20 formed into a stripe shape to extend along the resonator direction. The front surface of the second p-type guide layer 172 is exposed in a stripe shape from the opening 20. In other words, the insulation film 4 makes contact with the second p-type guide layer 172 at the opposite lateral sides of the opening 20.

The transparent electrode 5 is formed by laminating a first conductive film 21 and a second conductive film 22 in the named order from the side of the p-type semiconductor layer 12. The first conductive film 21 is made of an indium oxide-based material (e.g., ITO). The first conductive film 21 extends into the opening 20 and makes contact with the second p-type guide layer 172. The first conductive film 21 is formed to extend over the front surface of the insulation film 4 outside the opening 20. The second conductive film 22 is made of a zinc oxide-based material, a gallium oxide-based material or a tin oxide-based material (e.g., ZnO) and is formed to cover the entire area of the front surface of the first conductive film 21. A stripe-shaped recess portion corresponding to the opening 20 is formed on the front surface of the second conductive film 22. The transparent electrode 5 has a transmittance of 80% or more with respect to the light having the oscillation wavelength of the semiconductor laser device 107. The transparent electrode 5 is made of material other than nitride semiconductor. The resistivity of the transparent electrode 5 is 1×10⁻³ Ω·cm or less.

The p-side electrode pad 6 is a metal electrode making ohmic contact with the transparent electrode 5 and may be, e.g., a laminated electrode film formed by laminating a Ti layer, a TiN layer and an Au layer on the front surface of the transparent electrode 5 in the named order. A stripe-shaped recess portion corresponding to the opening 20 is formed on the front surface of the p-side electrode pad 6.

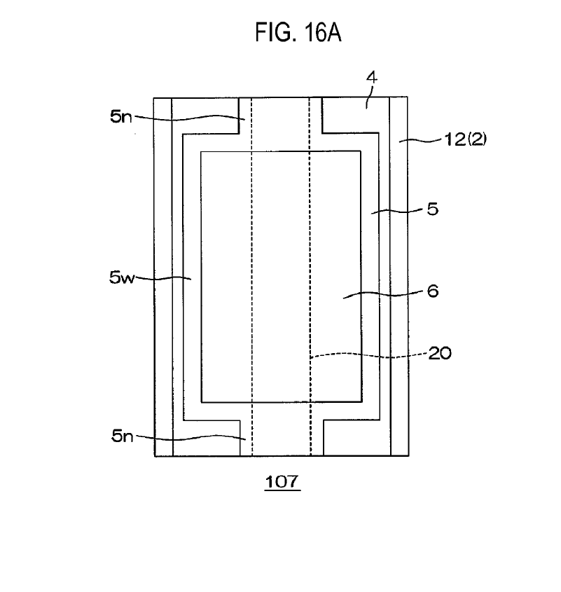

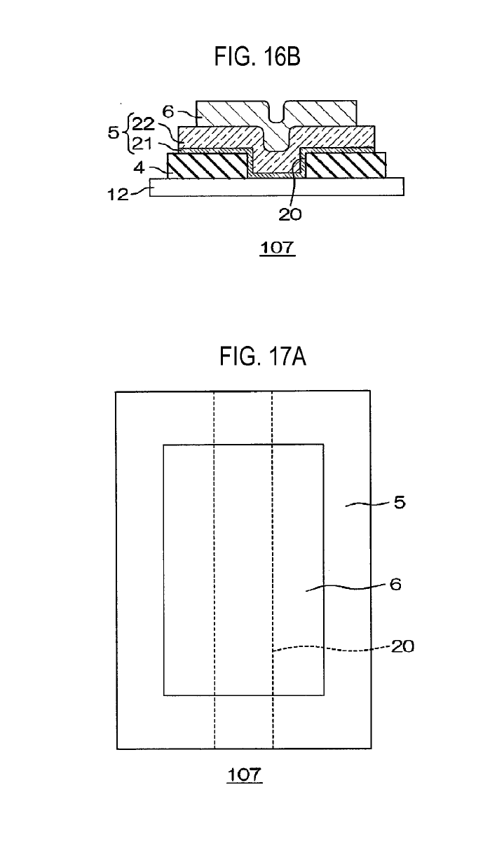

FIG. 16A is a diagrammatic plan view of the semiconductor laser device 107 according to the seventh embodiment. FIG. 16B is a schematic section view of a portion of the semiconductor laser device 107, showing a cross section orthogonal to the resonator direction parallel to the stripe-shaped opening 20. The insulation film 4 is formed into a substantially rectangular shape. The width of the insulation film 4 in the resonator intersecting direction orthogonal to the resonator direction (also orthogonal to the laminating direction of the nitride semiconductor laminate structure 2) is smaller than the width of the nitride semiconductor laminate structure 2 in the resonator intersecting direction. In other words, the opposite lateral edges of the insulation film 4 extending parallel to the resonator direction are respectively arranged inward of the opposite lateral edges of the nitride semiconductor laminate structure 2. The resonator-direction opposite end edges of the insulation film 4 are flush with the resonator-direction opposite end edges of the nitride semiconductor laminate structure 2.

The width of the transparent electrode 5 in the resonator intersecting direction is smaller than the width of the insulation film 4 in the resonator intersecting direction. In other words, the opposite lateral edges of the transparent electrode 5 extending parallel to the resonator direction are respectively arranged inward of the opposite lateral edges of the insulation film 4. More specifically, the width of the resonator-direction opposite end portions of the transparent electrode 5 is smaller than the width of the resonator-direction central portion of the transparent electrode 5. In other words, the transparent electrode 5 has a pair of narrow portions 5n arranged in the resonator-direction opposite end areas and a wide portion 5w arranged in the central area between the narrow portions 5n. The narrow portions 5n and the wide portion 5w are respectively formed into a rectangular shape. The end edges of the narrow portions 5n are flush with the end edges of the nitride semiconductor laminate structure 2. The resonator-direction opposite end edges of the wide portion 5w are respectively arranged inward of the resonator-direction opposite end edges of the nitride semiconductor laminate structure 2.

The p-side electrode pad 6 is formed into a substantially rectangular shape. The width of the p-side electrode pad 6 in the resonator intersecting direction is smaller than the width of the wide portion 5w of the transparent electrode 5 in the resonator intersecting direction. The length of the p-side electrode pad 6 in the resonator direction is smaller than the length of the wide portion 5w of the transparent electrode 5 in the resonator direction. In other words, the p-side electrode pad 6 is formed into a rectangular shape to have a size smaller than the size of the wide portion 5w of the transparent electrode 5. The opposite lateral edges and the opposite end edges of the p-side electrode pad 6 are respectively arranged inward of the opposite lateral edges and the opposite end edges of the wide portion 5w of the transparent electrode 5.

In the semiconductor laser device 107 configured as above, the first and second conductive films 21 and 22 serve as an upper clad layer and contribute to the light confinement in the light emitting layer 10. The first conductive film 21 made of an indium oxide-based material has a low contact resistance with respect to the p-type nitride semiconductor. The second conductive film 22 made of a zinc oxide-based material, a gallium oxide-based material or a tin oxide-based material shows a high growth rate. Accordingly, the transparent electrode 5 made up of the first and second conductive films 21 and 22 has a low contact resistance with respect to the p-type semiconductor layer 12 and can be formed into a necessary thickness for light confinement within a short period of time.

In the semiconductor laser device 107, the insulation film 4 having the opening 20 is formed on the p-type semiconductor layer 12. The first conductive film 21 makes contact with the p-type semiconductor layer 12 through the opening 20. Thus a current confinement structure is formed. This makes it possible to generate laser oscillation. The p-side electrode pad 6 making contact with the second conductive film 22 has a recess portion formed in the area of the p-side electrode pad 6 corresponding to the opening 20. Accordingly, when the p-side electrode pad 6 is arranged to face a mounting substrate and is bonded thereto by a junction-down method, there is no possibility that a large stress is applied to the area of the p-side electrode pad 6 corresponding to the opening 20 (the area where laser oscillation is generated). It is therefore possible to avoid generation of damage in the light emitting layer 10 during a bonding process. This makes it possible to improve the throughput and reliability of a product manufactured by bonding the semiconductor laser device to the mounting substrate by a junction-down method. Since the junction-down bonding can be employed with ease, it becomes possible to provide a product superior in heat dissipation property.

In the present embodiment, the first conductive film 21 and the second conductive film 22 make up the transparent electrode 5 whose width in the resonator intersecting direction is equal to or smaller than the width of the insulation film 4 in the resonator intersecting direction. Accordingly, the first conductive film 21 and the second conductive film 22 do not make contact with the nitride semiconductor laminate structure 2 in the area other than the opening 20. The width of the transparent electrode 5 is set as large as possible within a range not exceeding the width of the insulation film 4. This makes it possible to increase the width of the p-side electrode pad 6 formed on the transparent electrode 5. Since the width of the insulation film 4 is equal to or smaller than the width of the nitride semiconductor laminate structure 2, the width of the transparent electrode 5 becomes equal to or smaller than the width of the nitride semiconductor laminate structure 2. It is preferred that the transparent electrode 5 be formed as large as possible within a range not exceeding the width of the nitride semiconductor laminate structure 2. This makes it possible to increase the width of the p-side electrode pad 6 formed on the transparent electrode 5. Therefore, when junction-down bonding is employed, heat is dissipated through the p-side electrode pad 6.

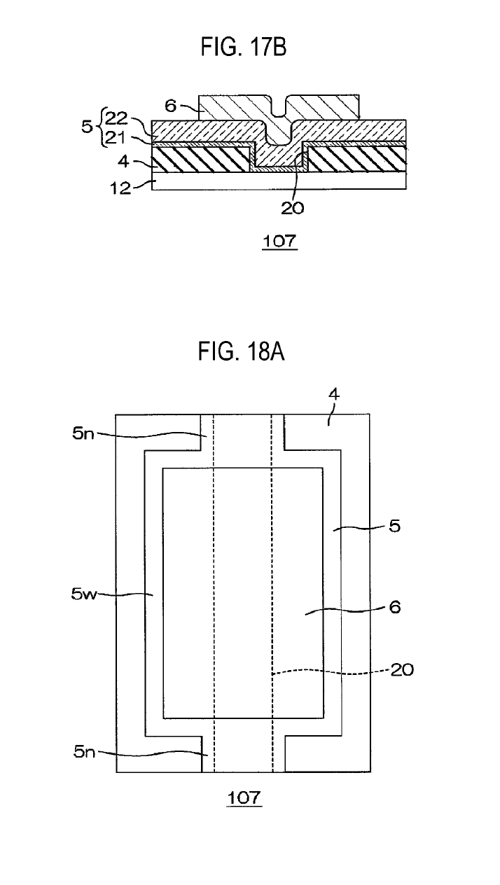

From this viewpoint, as in a first modified example of the seventh embodiment shown in FIG. 17A (a plan view) and FIG. 17B (a section view taken along the direction perpendicular to the resonator direction), the insulation film 4 may be formed over the entire area of the front surface of the p-type semiconductor layer 12 and the transparent electrode 5 may be formed over the entire area of the front surface of the insulation film 4. This makes it possible to maximize the area of the p-side electrode pad 6. It is preferred that the width of the p-side electrode pad 6 be set as large as possible within a range not exceeding the width of the transparent electrode 5. This makes it possible to increase the width of the p-side electrode pad 6. Therefore, when junction-down bonding is employed, heat is dissipated through the p-side electrode pad 6.

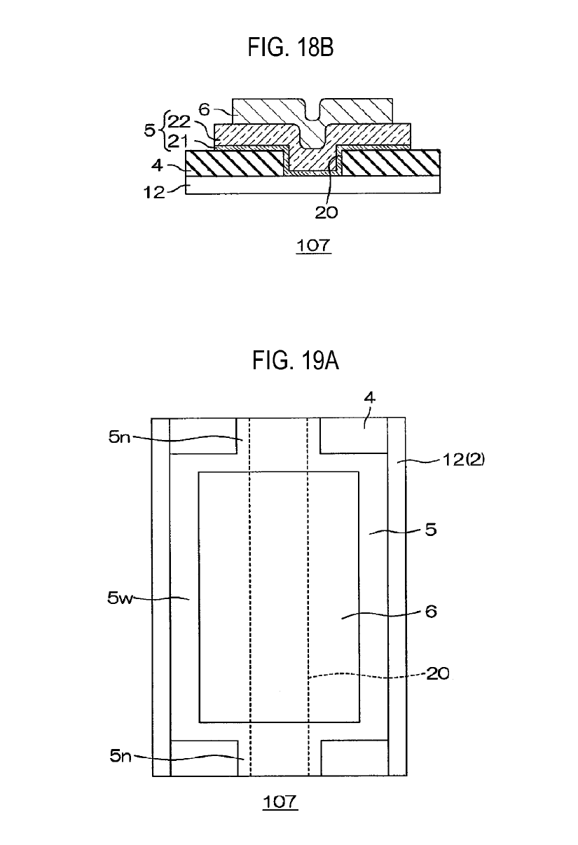

FIGS. 18A and 18B are plan and section views for explaining a second modified example of the seventh embodiment. This modified example differs from the example shown in FIGS. 16A and 16B in that the insulation film 4 is formed to cover the entire area of the front surface of the p-type semiconductor layer 12.

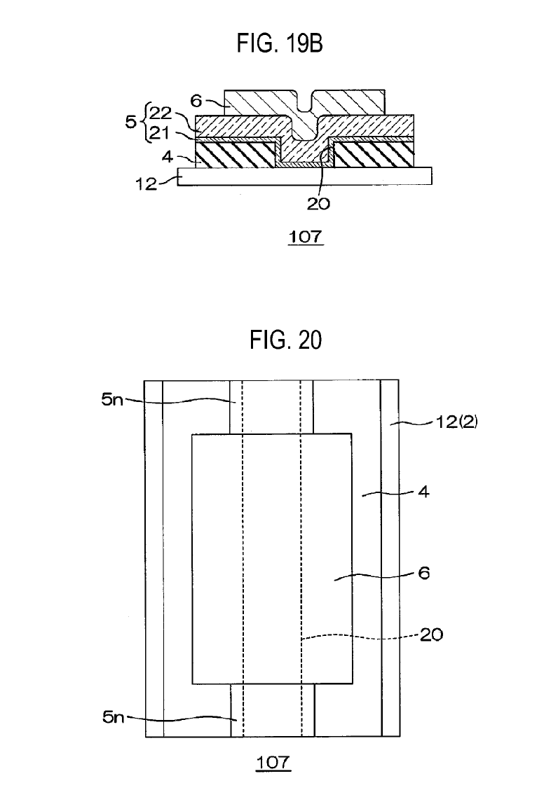

FIGS. 19A and 19B are plan and section views for explaining a third modified example of the seventh embodiment. This modified example differs from the example shown in FIGS. 16A and 16B in that the width of the wide portion 5w of the transparent electrode 5 is equal to the width of the insulation film 4 and in that the opposite lateral edges of the wide portion 5w are respectively flush with the opposite lateral edges of the insulation film 4.

FIG. 20 is a plan view showing a fourth modified example of the seventh embodiment. This modified example differs from the example shown in FIGS. 16A and 16B in that the p-side electrode pad 6 is formed to cover the entire area of the front surface of the wide portion 5w of the transparent electrode 5.

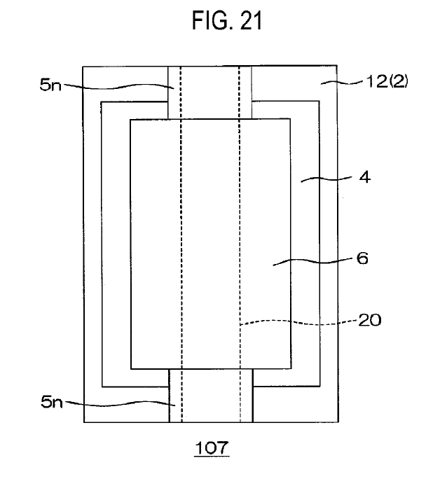

FIG. 21 is a plan view showing a fifth modified example of the seventh embodiment. This modified example differs from the example shown in FIG. 20 in that the resonator-direction opposite end edges of the insulation film 4 are respectively arranged inward of the resonator-direction opposite end edges of the p-type semiconductor layer 12.

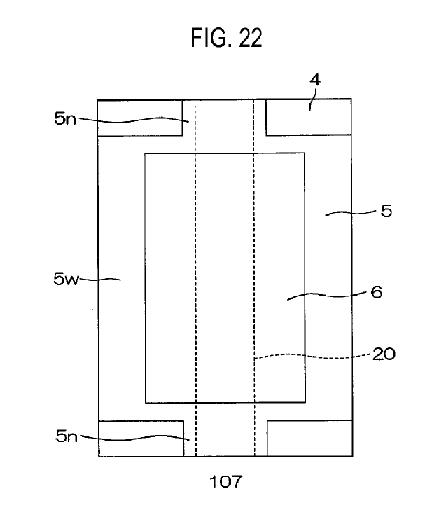

FIG. 22 is a plan view showing a sixth modified example of the seventh embodiment. This modified example differs from the example shown in FIGS. 16A and 16B in that the insulation film 4 is formed to cover the entire area of the front surface of the p-type semiconductor layer 12 and in that the opposite lateral edges of the wide portion 5w of the transparent electrode 5 are flush with the opposite lateral edges of the insulation film 4 (namely, the opposite lateral edges of the nitride semiconductor laminate structure 2).

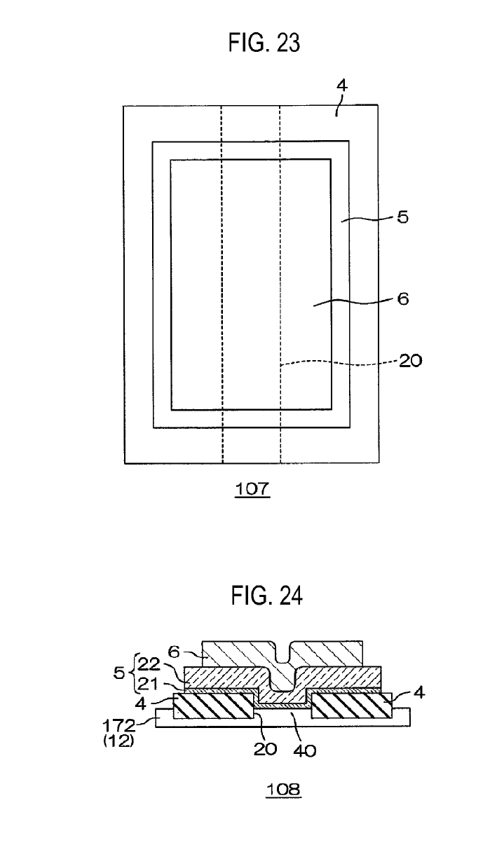

FIG. 23 is a plan view showing a seventh modified example of the seventh embodiment. In this modified example, the transparent electrode 5 made up of the first conductive film 21 and the second conductive film 22 is configured such that the opposite end edges thereof in the direction parallel to the resonator direction are respectively arranged inward of the opposite end edges of the nitride semiconductor laminate structure 2 in the same direction. In other words, the transparent electrode 5 of this modified example includes only the wide portion 5w of the transparent electrode 5 shown in FIG. 16A. In this modified example, the insulation film 4 is formed to cover the entire area of the front surface of the p-type semiconductor layer 12. Accordingly, the transparent electrode 5 does not make contact with the p-type semiconductor layer 12 in the resonator-direction opposite end portions, thereby providing a non-injection structure.

As set forth above, the shape and arrangement of the insulation film 4, the transparent electrode 5 and the p-side electrode pad 6 can be modified in many different forms.

FIG. 24 is a schematic partial section view of a semiconductor laser device according to an eighth embodiment of the present disclosure, showing a cross section taken along the direction orthogonal to the resonator direction. In FIG. 24, the portions corresponding to the respective portions of the semiconductor laser device shown in FIG. 16B will be designated by like reference symbols.

In the semiconductor laser device 108 of the eighth embodiment, the p-type semiconductor layer 12 includes a stripe-shaped ridge portion 40 formed to have a height of 0.5 μm or less. An opening 20 is formed in the insulation film 4 so as to expose the top surface of the ridge portion 40 therethrough. More specifically, the second p-type guide layer 172 serving as a p-type contact layer is dug down such that the ridge portion 40 having a height of 0.5 μm or less is formed in the second p-type guide layer 172. The insulation film 4 is arranged in the dug-down portions existing at the opposite lateral sides of the ridge portion 40. This makes it possible to have the insulation film 4 come closer to the light emitting layer 10, thereby enhancing the light confinement in the resonator intersecting direction and reducing the threshold value.

On the other hand, the ridge portion 40 having a height of 0.5 μm or less includes a top surface lower than the front surface of the insulation film 4. Therefore, even if the ridge portion 40 is formed in the p-type semiconductor layer 12, the p-side electrode pad 6 has a recess portion formed in the area corresponding to the opening 20 of the insulation film 4. This makes it possible to provide the semiconductor laser device 108 having a structure favorable for junction-down bonding, while enhancing the light confinement in the vertical direction by forming the ridge portion 40 in the p-type semiconductor layer 12.

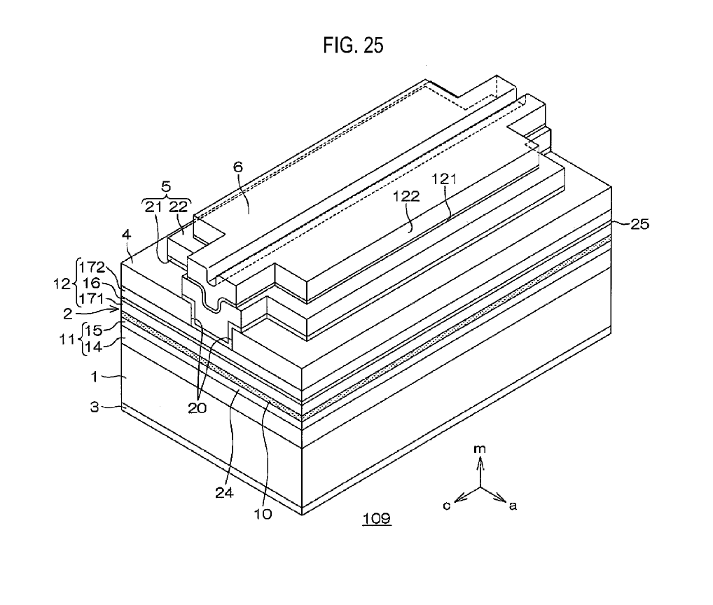

FIG. 25 is a schematic perspective view of a semiconductor laser device according to a ninth embodiment of the present disclosure, showing a cross section taken along the direction orthogonal to the resonator direction. In FIG. 25, the portions corresponding to the respective portions of the semiconductor laser device 107 of the seventh embodiment (shown in FIG. 15) will be designated by like reference symbols.

The semiconductor laser device 109 includes a substrate 1, a nitride semiconductor laminate structure 2, an n-side electrode pad 3, an insulation film 4, a transparent electrode 5 as an upper clad layer, and a p-side electrode pad 6. The nitride semiconductor laminate structure 2 includes an n-type semiconductor layer 11, a light emitting layer 10 and a p-type semiconductor layer 12, which are formed on the substrate 1 in the named order. The substrate 1 may be a GaN substrate having an m-plane as a major surface. The insulation film 4 is made of, e.g., SiO₂.

The n-type semiconductor layer 11 is formed by laminating an n-type clad layer 14 and an n-type guide layer 15 in the named order from the side of the substrate 1. The light emitting layer 10 is formed on the n-type guide layer 15.

The p-type semiconductor layer 12 includes a first p-type guide layer 171 formed on the light emitting layer 10, a p-type electron block layer 16 formed on the first p-type guide layer 171 and a second p-type guide layer 172 formed on the p-type electron block layer 16. The second p-type guide layer 172 serves as a p-type contact layer electrically connected to the transparent electrode 5. The second p-type guide layer 172 serving as a p-type contact layer may be doped with a p-type impurity (e.g., Mg) at a concentration of 1×10²⁰ cm ⁻³ or more. This makes it possible to reduce the contact resistance between the first conductive film 21 and the p-type semiconductor layer 12, thereby providing the semiconductor laser device 109 having a low series resistance.

The insulation film 4 has an opening 20 formed into a stripe shape to extend along the resonator direction. The front surface of the second p-type guide layer 172 is exposed in a stripe shape from the opening 20. In other words, the insulation film 4 makes contact with the second p-type guide layer 172 at the opposite lateral sides of the opening 20.

The transparent electrode 5 is formed by laminating a first conductive film 21 and a second conductive film 22 in the named order from the side of the p-type semiconductor layer 12. The first conductive film 21 is made of an indium oxide-based material (e.g., ITO). The first conductive film 21 extends into the opening 20 and makes contact with the second p-type guide layer 172. The first conductive film 21 is formed to extend over the front surface of the insulation film 4 outside the opening 20. The second conductive film 22 is made of a zinc oxide-based material, a gallium oxide-based material or a tin oxide-based material (e.g., ZnO) and is formed to cover the entire area of the front surface of the first conductive film 21. A stripe-shaped recess portion corresponding to the opening 20 is formed on the front surface of the second conductive film 22. The transparent electrode 5 has a transmittance of 80% or more with respect to the light having the oscillation wavelength of the semiconductor laser device 109. The transparent electrode 5 is made of material other than nitride semiconductor. The resistivity of the transparent electrode 5 is 1×10⁻³ Ω·cm or less.

The p-side electrode pad 6 is a metal electrode making ohmic contact with the transparent electrode 5 and may be, e.g., a laminated metal film formed by laminating a Ti layer 121 (a first metal film) and an Au layer 122 (a second metal film) on the front surface of the transparent electrode 5 in the named order. For example, the thickness of the Ti layer 121 may be about 50 nm and the thickness of the Au layer 122 may be about 500 nm. The Ti layer 121 may be formed by a sputtering method. The Au layer 122 may be formed by a vapor deposition method. A stripe-shaped recess portion corresponding to the opening 20 is formed on the front surface of the p-side electrode pad 6.

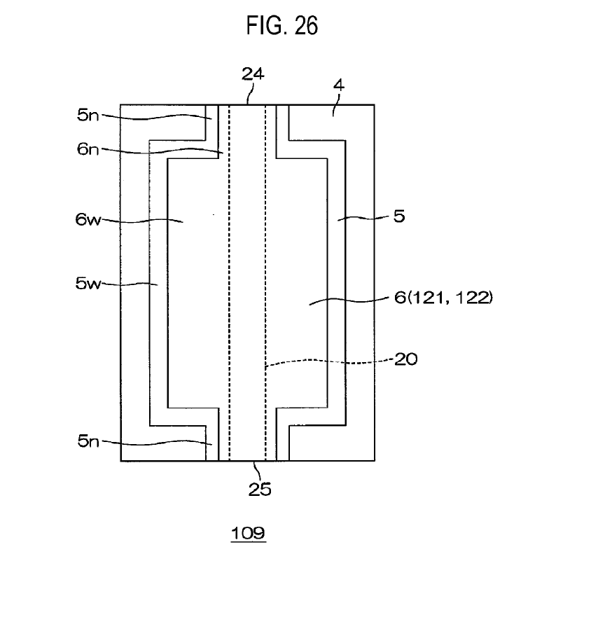

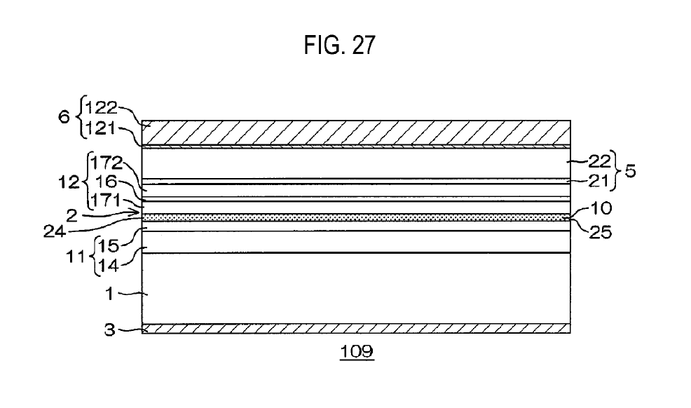

FIG. 26 is a diagrammatic plan view of the semiconductor laser device 109 according to the ninth embodiment. FIG. 27 is a schematic section view of the semiconductor laser device 109 according to the ninth embodiment, showing a cross section taken along the resonator direction parallel to the stripe-shaped opening 20.

The insulation film 4 is formed to cover the entire surface of the nitride semiconductor laminate structure 2. In other words, the insulation film 4 is formed into a substantially rectangular shape. The resonator-direction opposite end edges of the insulation film 4 are flush with the opposite end edges of the nitride semiconductor laminate structure 2 (namely, a pair of resonator end surfaces). The width of the insulation film 4 in the resonator intersecting direction orthogonal to the resonator direction (also orthogonal to the laminating direction of the nitride semiconductor laminate structure 2) is equal to the width of the nitride semiconductor laminate structure 2 in the resonator intersecting direction.

The width of the transparent electrode 5 in the resonator intersecting direction is smaller than the width of the insulation film 4 in the resonator intersecting direction. In other words, the opposite lateral edges of the transparent electrode 5 parallel to the resonator direction are respectively arranged inward of the opposite lateral edges of the insulation film 4. More specifically, the width of the resonator-direction opposite end portions of the transparent electrode 5 is smaller than the width of the resonator-direction central portion of the transparent electrode 5. In other words, the transparent electrode 5 has a pair of narrow portions 5n arranged in the resonator-direction opposite end areas and a wide portion 5w arranged in the central area between the narrow portions 5n. The narrow portions 5n and the wide portion 5w are respectively formed into a rectangular shape. The end edges of the narrow portions 5n are flush with the end edges of the nitride semiconductor laminate structure 2 (namely, the resonator end surfaces 24 and 25). Accordingly, the transparent electrode 5 extends over the total length in the resonator direction and the opposite end edges of the transparent electrode 5 are respectively flush with the resonator end surfaces 24 and 25. The resonator-direction opposite end edges of the wide portion 5w are respectively arranged inward of the resonator-direction opposite end edges of the nitride semiconductor laminate structure 2.

The p-side electrode pad 6 is identical in shape with the transparent electrode 5. In other words, the p-side electrode pad 6 has a pair of narrow portions 6n arranged in the resonator-direction opposite end areas and a wide portion 6w arranged in the central area between the narrow portions 6n. The narrow portions 6n and the wide portion 6w are respectively formed into a rectangular shape. The end edges of the narrow portions 6n are flush with the end edges of the nitride semiconductor laminate structure 2 (namely, the resonator end surfaces 24 and 25). Accordingly, the p-side electrode pad 6 extends over the total length in the resonator direction and the opposite end edges of the p-side electrode pad 6 are respectively flush with the resonator end surfaces 24 and 25. The opposite lateral edges of the narrow portions 6n extending along the resonator direction are respectively arranged inward of the corresponding opposite lateral edges of the narrow portions 5n of the transparent electrode 5 by a specified distance. The resonator-direction opposite end edges of the wide portion 6w are respectively arranged inward of the corresponding opposite end edges of the wide portion 5w of the transparent electrode 5 by a specified distance. In the present embodiment, the Ti layer 121 and the Au layer 122 making up the p-side electrode pad 6 are formed into the same pattern.

In the semiconductor laser device 109 configured as above, the first and second conductive films 21 and 22 serve as an upper clad layer and contribute to the light confinement in the light emitting layer 10. The first conductive film 21 made of an indium oxide-based material has a low contact resistance with respect to the p-type nitride semiconductor. The second conductive film 22 made of a zinc oxide-based material, a gallium oxide-based material or a tin oxide-based material shows a high growth rate. Accordingly, the transparent electrode 5 made up of the first and second conductive films 21 and 22 has a low contact resistance with respect to the p-type semiconductor layer 12 and can be formed into a necessary thickness for light confinement within a short period of time.

In the semiconductor laser device 109, the insulation film 4 having the opening 20 is formed on the p-type semiconductor layer 12. The first conductive film 21 makes contact with the p-type semiconductor layer 12 through the opening 20. Thus a current confinement structure is formed. This makes it possible to generate laser oscillation. The p-side electrode pad 6 making contact with the second conductive film 22 has a recess portion formed in the area of the p-side electrode pad 6 corresponding to the opening 20. Accordingly, when the p-side electrode pad 6 is arranged to face a mounting substrate and is bonded thereto by a junction-down method, there is no possibility that a large stress is applied to the area of the p-side electrode pad 6 corresponding to the opening 20 (the area where laser oscillation is generated). It is therefore possible to avoid generation of damage in the light emitting layer 10 during a bonding process. This makes it possible to improve the throughput and reliability of a product manufactured by bonding the semiconductor laser device to the mounting substrate by a junction-down method. Since the junction-down bonding can be employed with ease, it becomes possible to provide a product superior in heat dissipation property.

In the present embodiment, as best shown in FIG. 27, the p-side electrode pad 6 formed of a laminated metal film extends over the total length in the resonator direction, namely over the range running from one resonator end surface 24 to the other resonator end surface 25. This makes it possible to keep the current density uniform in all places along the total length in the resonator direction. It is therefore possible to realize a semiconductor laser device 109 having superior characteristics.

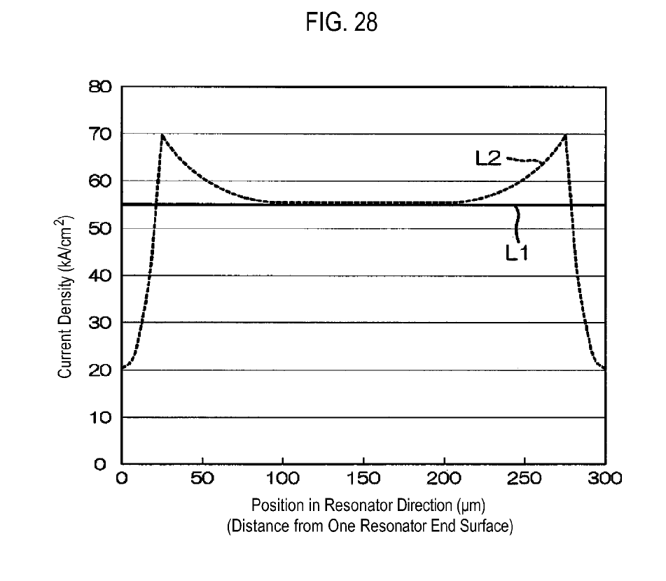

FIG. 28 represents the simulation results for calculation of the current densities in the respective portions along the resonator direction (the current densities in the interface between the p-type semiconductor layer 12 and the transparent electrode 5). Curve L1 indicates the current density in case of the configuration of the ninth embodiment shown in FIG. 25. Curve L2 indicates the current density in case of the configuration of the seventh embodiment shown in FIG. 15, namely the current density in case of the configuration in which the opposite end edges of the p-side electrode pad 6 are arranged inward of the resonator end surfaces. In the configuration in which the opposite end edges of the p-side electrode pad 6 are arranged inward of the resonator end surfaces (indicated by curve L2), the current density is sharply dropped near the resonator end surfaces. This is because the specific resistance of the transparent electrode 5 is higher than the specific resistance of the p-side electrode pad 6 and because the electric current supplied to the regions near the resonator end surfaces is insufficient. In particular, the specific resistance of the material making up the second conductive film 22 is high. For example, the specific resistance of ZnO is 5×10⁻⁴ Ω·cm which is about two digits higher than the specific resistance of metal. Peaks attributable to the electric field concentration appear in the regions near the end edges of the p-side electrode pad 6. As stated above, the current density is not constant in the resonator direction. In the configuration of the ninth embodiment (indicated by curve L1), however, it is possible to make the current density constant over the total length (e.g., 300 μm) in the resonator direction.

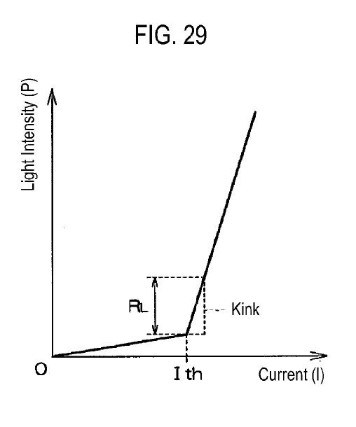

FIG. 29 is a light output characteristic diagram for illustrating the improvement of the light output characteristics in the ninth embodiment. In FIG. 29, there is shown the relationship between the electric current I and the light intensity P. With the configuration of the ninth embodiment, the light intensity P is linearly changed with respect to the electric current I in the range exceeding the threshold current Ith. In case where the opposite end edges of the p-side electrode pad 6 are arranged inward of the resonator end surfaces, an L-like kink (bend) is generated in the low output region R_{L} near the threshold current Ith as indicated by dot lines. For that reason, it becomes impossible to generate laser oscillation in the low output region R_{L}. With the configuration of the ninth embodiment, it is therefore possible to improve the light output characteristics and to secure the linearity of light output in a wide range from a low output to a high output.

In the ninth embodiment, the laminated metal film making up the p-side electrode pad 6 need not be necessarily the Ti/Au film but may be, e.g., a Ti/Ni/Au film, a Ti/TiN/Au film, a TiN/Au film, a TiN/Al film, a Ti/Pt/Au film, a Ti/Pd/Au film, a Pt/Au film or a Pd/Au film.

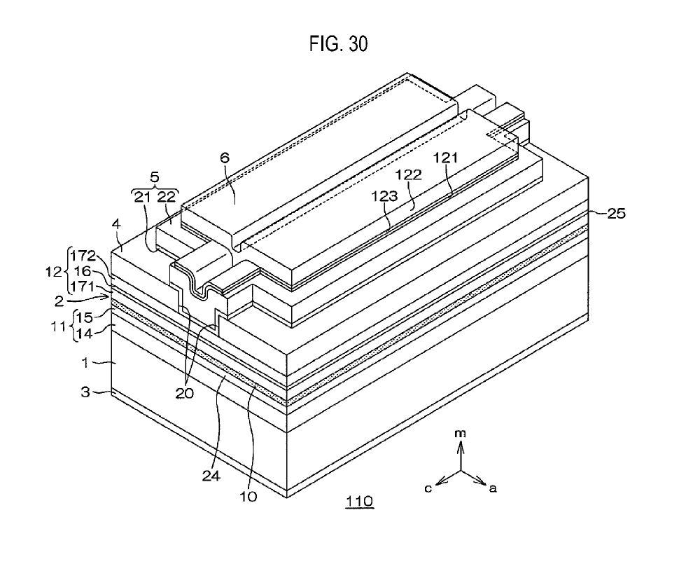

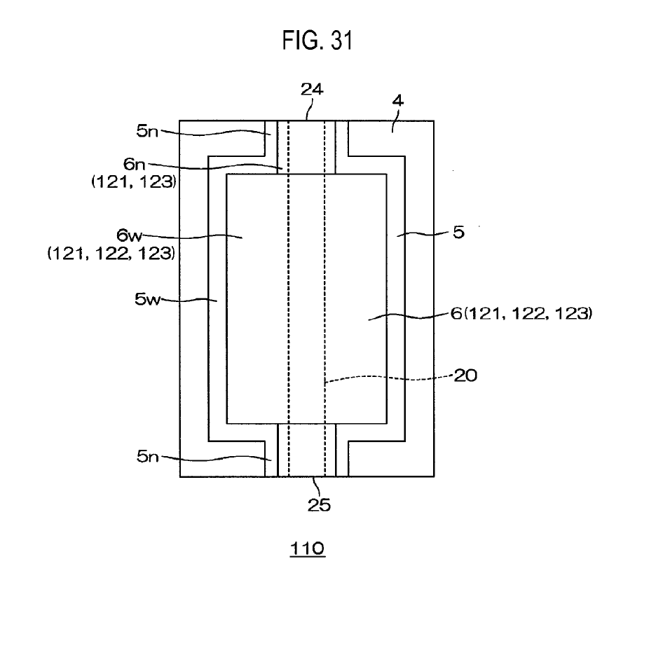

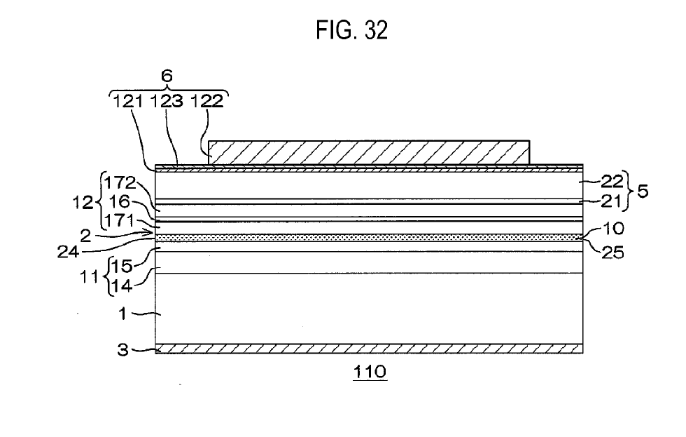

FIG. 30 is a schematic perspective view of a semiconductor laser device according to a tenth embodiment of the present disclosure. FIG. 31 is a schematic plan view of the semiconductor laser device of the tenth embodiment. FIG. 32 is a vertical section view of the semiconductor laser device of the tenth embodiment, which is taken along the resonator direction. In FIGS. 30 through 32, the portions corresponding to the respective portions of the semiconductor laser device shown in FIGS. 25 through 27 are designated by like reference symbols.

In the semiconductor laser device 110, the p-side electrode pad 6 has a pair of narrow portions 6n arranged in the resonator-direction opposite end areas and a wide portion 6w arranged in the central area between the narrow portions 6n. The narrow portions 6n and the wide portion 6w are respectively formed into a rectangular shape. The end edges of the narrow portions 6n are flush with the end edges of the nitride semiconductor laminate structure 2 (namely, the resonator end surfaces 24 and 25). Accordingly, the p-side electrode pad 6 extends over the total length in the resonator direction and the opposite end edges of the p-side electrode pad 6 are respectively flush with the resonator end surfaces 24 and 25. The opposite lateral edges of the narrow portions 6n extending along the resonator direction are respectively arranged inward of the corresponding opposite lateral edges of the narrow portions 5n of the transparent electrode 5 by a specified distance. The resonator-direction opposite end edges of the wide portion 6w are respectively arranged inward of the corresponding opposite end edges of the wide portion 5w of the transparent electrode 5 by a specified distance.

In the present embodiment, the p-side electrode pad 6 is made up of a laminated metal film formed by laminating a Ti layer 121 (a first metal film), a Ni layer 123 (a third metal layer) and an Au layer 122 (a second metal film) on the front surface of the transparent electrode 5 in the named order. For example, the thickness of the Ti layer 121 may be about 50 nm. The thickness of the Ni layer 123 may be about 50 nm The thickness of the Au layer 122 may be about 500 nm. The Ti layer 121 and the Ni layer 123 may be formed by a sputtering method continuously performed within one and the same chamber. The Au layer 122 may be formed by a vapor deposition method. In the present embodiment, the Ti layer 121 and the Ni layer 123 are formed into the same shape. The Au layer 122 is formed into a shape differing from the shape of the Ti layer 121 and the Ni layer 123. More specifically, the wide portion 6w of the p-side electrode pad 6 is formed of a laminated metal film including the Ti layer 121, the Ni layer 123 and the Au layer 122. On the other hand, the narrow portions 6n are formed of a laminated metal film including the Ti layer 121 and the Ni layer 123. The Au layer 122 is not formed in the narrow portions 6n. In other words, the resonator-direction opposite end edges of the Au layer 122 are respectively arranged inward of the resonator end surfaces 24 and 25 by a specified distance (e.g., 25 μm). Insofar as the end edges of the Au layer 122 are arranged inward of the resonator end surfaces 24 and 25, a portion of the narrow portions 6n may be formed of a laminated metal film including the Ti layer 121, the Ni layer 123 and the Au layer 122.

The Ni layer 123 can serve as an etching stop layer when the Au layer 122 is patterned by dry etching (e.g., reactive ion etching). In other words, the Ni layer 123 is a metal film resistant to the etching of the Au layer 122.

With this configuration, just like the ninth embodiment, the p-side electrode pad 6 made of metal makes contact with the transparent electrode 5 over the total length in the resonator direction. This makes it possible to make the current density constant everywhere along the resonator direction, thereby improving the light output characteristics. In the present embodiment, the resonator-direction end edges of the Au layer 122 are arranged inward of the resonator end surfaces 24 and 25. Accordingly, it is possible to avoid a situation that, when the resonator end surfaces 24 and 25 are formed by cleaving the substrate 1 in the manufacturing process of the semiconductor laser device 110, the Au layer 122 is stretched, due to its ductility, to thereby cover the resonator end surfaces 24 and 25. In other words, some portions of the Au layer 122 (adjoining to the resonator end surfaces) are selectively etched away after forming the laminated metal film making up the p-side electrode pad 6. Thereafter, the resonator end surfaces 24 and 25 are formed by cleaving the substrate 1. In this manner, the resonator end surfaces 24 and 25 can be formed with no influence of the Au layer 122. This makes it possible to realize the semiconductor laser device 110 with enhanced characteristics.

In the present embodiment, the laminated metal film making up the p-side electrode pad 6 need not be necessarily the Ti/Ni/Au film but may be, e.g., a Ni/Au film, a Ti/Pt/Au film, a Ti/Pd/Au film, a Pt/Au film, a Pd/Au film, a Ti/Cr/Au film or a Cr/Au film. In case where the first metal film making contact with the transparent electrode 5 is made of a material (e.g., Ni, Pt, Pd or Cr) resistant to the etching of the Au layer 122, the p-side electrode pad 6 need not be necessarily the three-layer structure. Alternatively, the p-side electrode pad 6 may be formed of a laminated metal film having a two-layer structure by forming an Au layer to make contact with the first metal film.

While ten embodiments of the present disclosure have been described above, the present disclosure can be embodied in other forms. For example, the thickness and the impurity concentration of the respective layers and films making up the nitride semiconductor laminate structure 2 and the transparent electrode 5 are nothing more than one example. Other values can be arbitrarily selected and used as the thickness and the impurity concentration. The n-type clad layer 14 need not be necessarily the single AlGaN layer but may be a super-lattice layer formed of an AlGaN layer and a GaN layer.

While AlGaN and GaN have been taken as examples of the nitride semiconductor in the foregoing embodiments, it may be possible to use other nitride semiconductors such as aluminum nitride (AlN) and indium nitride (InN). The nitride semiconductor can be generally represented by AlₓIn_{y}Ga_{1-x-y}N (where 0≦x≦1, 0≦y≦1 and 0≦x+y≦1).

In the first embodiment described above, the nitride semiconductor laminate structure 2 has the m-plane as a major growth surface and the resonator direction coincides with the c-axis direction. Alternatively, the resonator direction may coincide with the a-axis direction. The present disclosure can be applied to a case where the same laser structure is formed by the nitride semiconductor laminate structure 2 having the a-plane or the c-plane as a major growth surface. In the event that the m-plane is used as a major growth surface as in the foregoing embodiments, the longitudinal direction of the opening 20 of the insulation film 4 is perpendicular to the c-plane. If the c-plane is used as a major growth surface, the longitudinal direction of the opening 20 of the insulation film 4 is perpendicular to the m-plane. If the (20-12) surface is used as a major growth surface, the longitudinal direction of the opening 20 of the insulation film 4 is perpendicular to the (10-14) surface. The longitudinal direction stated above is the resonator direction.

The first conductive film 21 covers the entire areas of the front surface of the insulation film 4, the slant surfaces 4A defining the opening 20 of the insulation film 4 and the front surface of the p-type guide contact layer 17 exposed through the opening 20. Alternatively, as indicated by dot lines in FIG. 1, the first conductive film 21 may cover at least the front surface of the p-type guide contact layer 17 exposed through the opening 20 and the front surface of the insulation film 4 within a range of about 50 μm from the periphery of the opening 20.

A semiconductor laser device having no substrate can be manufactured by removing the substrate 1 by a laser lift-off method or other methods after forming the nitride semiconductor laminate structure 2.

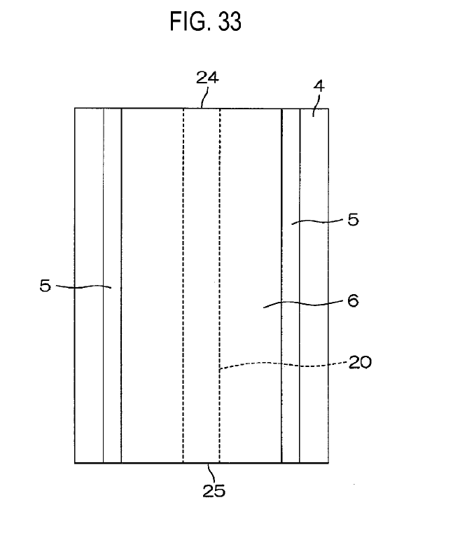

The configuration of the ninth embodiment shown in FIG. 25 may be modified in such a fashion that, as shown in FIG. 33, the transparent electrode 5 is formed into a rectangular shape to extend at an equal width over the total length in the resonator direction. In this case, the p-side electrode pad 6 may have a width equal to or smaller than the width of the transparent electrode 5 and may be formed into a rectangular shape to extend at an equal width over the total length in the resonator direction. The resonator-direction opposite end edges of the p-side electrode pad 6 may be respectively flush with the resonator end surfaces 24 and 25.

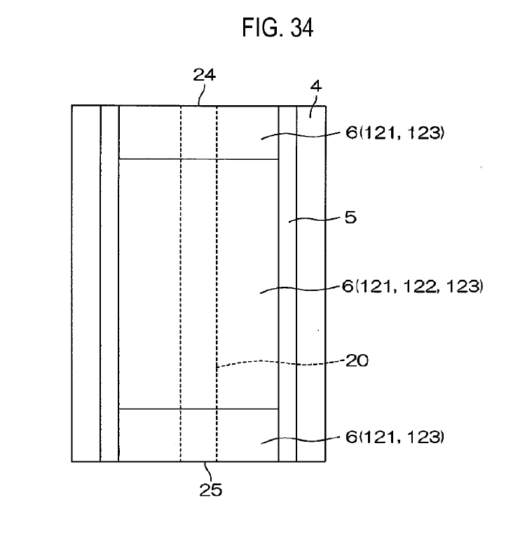

The configuration of the tenth embodiment shown in FIG. 30 can also be modified in the same manner. In other words, as shown in FIG. 34, the transparent electrode 5 is formed into a rectangular shape to extend at an equal width over the total length in the resonator direction. The p-side electrode pad 6 has a width equal to or smaller than the width of the transparent electrode 5 and is formed into a rectangular shape to extend at an equal width over the total length in the resonator direction. In the laminated metal film making up the p-side electrode pad 6, the resonator-direction opposite end edges of the Au layer 122 are respectively arranged inward of the resonator end surfaces 24 and 25. In the laminated metal film making up the p-side electrode pad 6, the resonator-direction opposite end edges of the Ti layer 121 and the Ni layer 123 may be respectively flush with the resonator end surfaces 24 and 25.

The electrode structures described in respect of the seventh, ninth and tenth embodiments and the modified examples thereof can be equally applied to the structures of the remaining embodiments.

While certain embodiments have been described, these embodiments have been presented by way of example only, and are not intended to limit the scope of the disclosures. Indeed, the novel devices described herein may be embodied in a variety of other forms; furthermore, various omissions, substitutions, combinations and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer, the nitride semiconductor laminate structure not including a p-type semiconductor clad layer; and
an upper clad layer formed on the p-type semiconductor layer,
the upper clad layer including a first conductive film made of an indium oxide-based material and a second conductive film formed on the first conductive film and made of a zinc oxide-based material, a gallium oxide-based material or a tin oxide-based material.

2. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer; and
an upper clad layer formed on the p-type semiconductor layer,
the upper clad layer including a first conductive film made of an indium oxide-based material and a second conductive film formed on the first conductive film and made of a zinc oxide-based material, a gallium oxide-based material or a tin oxide-based material,
the semiconductor laser device not comprising a clad layer made of a p-type nitride semiconductor.

3. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer; and
an upper clad layer formed on the p-type semiconductor layer,
the upper clad layer including a first conductive film made of an indium oxide-based material and a second conductive film formed on the first conductive film and made of a zinc oxide-based material, a gallium oxide-based material or a tin oxide-based material,
the p-type semiconductor layer including a p-type guide layer formed in a surface layer portion near the upper clad layer, the p-type guide layer making contact with the first conductive film.

4. The device of claim 3, wherein the p-type guide layer is made of InGaN.

5. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer;
an insulation film formed on the p-type semiconductor layer, the insulation film having an opening; and
an upper clad layer formed on the insulation film to make contact with the p-type semiconductor layer through the opening,
the upper clad layer including a first conductive film formed on the insulation film to make contact with the p-type semiconductor layer through the opening and made of an indium oxide-based material and a second conductive film formed on the first conductive film and made of a zinc oxide-based material, a gallium oxide-based material or a tin oxide-based material.

6. The device of claim 5, wherein the opening has a width of 1 μm or more and 100 μm or less when seen in a plan view from a thickness direction of the insulation film.

7. The device of claim 5, wherein the insulation film has a thickness of 200 nm or more and 400 nm or less.

8. The device of claim 1, wherein the first conductive film has an electron concentration of 1×10¹⁹ cm ⁻³ or more.

9. The device of claim 1, wherein the first conductive film has a transmittance of 70% or more with respect to an emission wavelength of the light emitting layer.

10. The device of claim 1, wherein the second conductive film has a transmittance of 70% or more with respect to an emission wavelength of the light emitting layer.

11. The device of claim 1, wherein the first conductive film includes Sn at a composition ratio of 3% or more.

12. The device of claim 1, wherein a contact resistance between the p-type semiconductor layer and the first conductive film is 1×10⁻³ Ω·cm² or less.

13. The device of claim 1, wherein the first conductive film is made of ITO.

14. The device of claim 1, wherein the first conductive film has a thickness of 2 nm or more and 30 nm or less.

15. The device of claim 1, wherein the second conductive film is made of ZnO including group-III atoms at a concentration of 1×10¹⁹ cm⁻³ or more.

16. The device of claim 1, wherein the second conductive film is made of MgZnO including group-III atoms at a concentration of 1×10¹⁹ cm⁻³ or more.

17. The device of claim 1, wherein the second conductive film is made of MgZnO including group-III atoms at a concentration of 1×10¹⁹ cm⁻³ or more and having an Mg composition ratio of 50% or less.

18. The device of claim 15, wherein the group-III atoms are Ga atoms or Al atoms.

19. The device of claim 1, wherein the second conductive film has a thickness of 400 nm or more and 600 nm or less.

20. The device of claim 1, wherein the first conductive film and the second conductive film is smaller in refractive index than the light emitting layer.

21. The device of claim 1, wherein the p-type semiconductor layer includes Mg at a concentration of 1×10¹⁹ cm⁻³ or more.

22. The device of claim 1, wherein the light emitting layer is made of InGaN.

23. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer;
a first conductive film formed on the p-type semiconductor layer and made of an indium oxide-based material;
a second conductive film formed on the first conductive film and made of a zinc oxide-based material, a gallium oxide-based material or a tin oxide-based material, the p-type semiconductor layer including an electron block layer made of p-type AlGaN or p-type AlInGaN having an Al composition ratio of 18% or more, the p-type semiconductor layer having a stripe-shaped ridge portion extending in a resonator direction, the p-type semiconductor layer having a thickness of 50 nm or more in the ridge portion; and
an insulation film making contact with the p-type semiconductor layer at opposite lateral sides of the ridge portion, the first conductive film making contact with the p-type semiconductor layer in the ridge portion and extending over the insulation film.

24. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer;
a first conductive film formed on the p-type semiconductor layer and made of an indium oxide-based material; and
a second conductive film formed on the first conductive film and made of a zinc oxide-based material, a gallium oxide-based material or a tin oxide-based material,
the p-type semiconductor layer including a first p-type guide layer formed on the light emitting layer and a second p-type guide layer formed on the first p-type guide layer, the second p-type guide layer having a thickness of 10 nm or more and 50 nm or less, the second p-type guide layer doped with a p-type impurity at a concentration of 1×10²⁰ cm⁻³ or more.

25. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer;
a first conductive film formed on the p-type semiconductor layer and made of an indium oxide-based material; and
a second conductive film formed on the first conductive film and made of a zinc oxide-based material, a gallium oxide-based material or a tin oxide-based material, the p-type semiconductor layer including a first p-type guide layer formed on the light emitting layer, an electron block layer formed on the first p-type guide layer and made of p-type AlGaN or p-type AlInGaN having an Al composition ratio of 18% or more and a second p-type guide layer formed on the electron block layer, the second p-type guide layer having a thickness of 10 nm or more and 50 nm or less, the second p-type guide layer doped with a p-type impurity at a concentration of 1×10²⁰ cm⁻³ or more.

26. The device of claim 23, wherein the first conductive film is made of ITO having an indium composition ratio of 90% or more.

27. The device of claim 23, wherein the first conductive film and the second conductive film have a total thickness of 400 nm or more.

28. The device of claim 23, further comprising:
a p-side electrode pad formed on the second conductive film, the second conductive film being larger in width in a direction orthogonal to the resonator direction than the p-side electrode pad.

29. The device of claim 28, further comprising:
a mount member having a device mount surface, the p-side electrode pad arranged to face the device mount surface and bonded to the device mount surface.

30. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer;
a first conductive film formed on the p-type semiconductor layer and made of an indium oxide-based material; and
a second conductive film formed on the first conductive film and made of a zinc oxide-based material, a gallium oxide-based material or a tin oxide-based material,
the p-type semiconductor layer including a first p-type guide layer formed on the light emitting layer, a p-type electron block layer formed on the first p-type guide layer, a second p-type guide layer formed on the p-type electron block layer, the second p-type guide layer being higher in p-type impurity concentration than the first p-type guide layer, and a p-type contact layer formed on the second p-type guide layer, the p-type contact layer being higher in p-type impurity concentration than the second p-type guide layer.

31. The device of claim 30, wherein at least a portion of the p-type contact layer is dug down to form a ridge portion.

32. The device of claim 30, wherein the second p-type guide layer has a thickness of 50 nm or less.

33. The device of claim 30, wherein the p-type contact layer has a p-type impurity concentration of 1×10²⁰ cm⁻³ or more, and the first p-type guide layer and the second p-type guide layer have a p-type impurity concentration of 5×10¹⁸ cm⁻³ or more and 5×10¹⁹ cm⁻³ or less.

34. The device of claim 30, wherein the p-type semiconductor layer has a total thickness of 1500 Å or less.

35. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer;
a first conductive film formed on the p-type semiconductor layer and made of an indium oxide-based material;
a second conductive film formed on the first conductive film and made of a zinc oxide-based material, a gallium oxide-based material or a tin oxide-based material; and
a p-side electrode pad formed to make contact with the second conductive film, the p-side electrode pad including TiN.

36. The device of claim 35, wherein the p-side electrode pad includes a laminated electrode film having a Ti layer, a TiN layer and an Au layer laminated in the named order from the side of the second conductive film.

37. The device of claim 35, further comprising:
a mount member having a device mount surface, the p-side electrode pad arranged to face the device mount surface and bonded to the device mount surface.

38. The device of claim 35, further comprising:
an n-side electrode pad bonded to the nitride semiconductor laminate structure at the opposite side of the light emitting layer from the p-side electrode pad, the n-side electrode pad including TiN.

39. The device of claim 38, wherein the n-side electrode pad includes a laminated electrode film having an Al layer, a TiN layer and an Au layer laminated in the named order from the side of the nitride semiconductor laminate structure.

40. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer;
an insulation film formed on the p-type semiconductor layer, the insulation film having an opening;
a first conductive film formed on the insulation film to make contact with the p-type semiconductor layer through the opening and made of an indium oxide-based material;
a second conductive film formed on the first conductive film and made of a zinc oxide-based material, a gallium oxide-based material or a tin oxide-based material; and
a p-side electrode pad formed to make contact with the second conductive film, the p-side electrode pad having a recess portion formed in an area corresponding to the opening.

41. The device of claim 40, wherein the opening is formed into a stripe, and the first conductive film and the second conductive film make up a transparent electrode whose width in a direction perpendicular to the stripe is equal to or smaller than a width of the insulation film in the direction perpendicular to the stripe.

42. The device of claim 40, wherein the opening is formed into a stripe, and the first conductive film and the second conductive film make up a transparent electrode whose width in a direction perpendicular to the stripe is equal to or smaller than a width of the nitride semiconductor laminate structure in the direction perpendicular to the stripe.

43. The device of claim 41, wherein a width of the p-side electrode pad in a direction orthogonal to the stripe is equal to or smaller than a width of the transparent electrode in the direction orthogonal to the stripe.

44. The device of claim 40, wherein the opening is formed into a stripe, and the first conductive film and the second conductive film make up a transparent electrode whose opposite end edges in a direction parallel to the stripe are respectively arranged inward of opposite end edges of the nitride semiconductor laminate structure in the direction parallel to the stripe.

45. The device of claim 40, wherein the opening is formed into a stripe, and the first conductive film and the second conductive film make up a transparent electrode having opposite end portions and a central portion arranged along a direction parallel to the stripe, the opposite end portions differing in width from the central portion.

46. The device of claim 40, wherein the p-type semiconductor layer includes a stripe-shaped ridge portion formed to have a height of 0.5 μm or less, the opening formed so as to expose a top surface of the ridge portion.

47. The device of claim 40, wherein the p-type semiconductor layer includes a p-type contact layer having a front surface exposed through the opening, the p-type contact layer having a p-type impurity concentration of 1×10²⁰ cm⁻³ or more.

48. A semiconductor laser device, comprising:
a nitride semiconductor laminate structure including an n-type clad layer, an n-type guide layer formed on the n-type clad layer, a light emitting layer formed on the n-type guide layer and a p-type semiconductor layer formed on the light emitting layer, the nitride semiconductor laminate structure having a pair of resonator end surfaces existing at opposite ends in a resonator direction;
an insulation film formed on the p-type semiconductor layer, the insulation film having a stripe-shaped opening extending along the resonator direction;
a first conductive film formed on the insulation film to make contact with the p-type semiconductor layer through the opening and made of an indium oxide-based material;
a second conductive film formed on the first conductive film and made of a zinc oxide-based material, a gallium oxide-based material or a tin oxide-based material; and
a p-side electrode pad formed to make contact with the second conductive film, the p-side electrode pad having a pair of end edges respectively flush with the resonator end surfaces.

49. The device of claim 48, wherein the p-side electrode pad is formed of a laminated metal film including a first metal film making contact with the second conductive film and a second metal film formed on the first metal film, the first metal film having opposite end edges in the resonator direction respectively flush with the resonator end surfaces, the second metal film having opposite end edges in the resonator direction respectively arranged inward of the resonator end surfaces by a specified distance.

50. The device of claim 49, wherein the laminated metal film making up the p-side electrode pad is arranged between the first metal film and the second metal film and further includes a third metal film resistant to etching of the second metal film.

51. The device of claim 49, wherein the first metal film is resistant to etching of the second metal film.

52. The device of claim 49, wherein the second metal film is made of gold.
